(19) United States
(12) Patent Application Publication
(10) Pub. No.: US 2006/0049419 A1
(43) Pub. Date: Mar. 9, 2006

(54) Light emitting diode device

(76) Inventors: Shinichi Tanaka, Tokyo (JP); Masatoshi Horii, Tokyo (JP); Akio Ogawa, Tokyo (JP); Yukitoshi Jinde, Tokyo (JP); Yasuyuki Kawakami, Tokyo (JP)

Correspondence Address: CERMAK & KENEALY, LLP, 515 EAST BRADDOCK RD SUITE B, Alexandria, VA, 22314, US

(21) Appl. No.: 11/218,660

(22) Filed: Sep. 6, 2005

(30) Foreign Application Priority Data
Sep. 3, 2004 (JP) 2004-257169
Dec. 2, 2004 (JP) 2004-349769
Mar. 28, 2005 (JP) 2005-091894

(51) Int. Cl. H01L 33/00

(52) U.S. Cl. 257/98

(57) ABSTRACT

A light emitting diode device can include a pair of opposed electrodes and a thin film multilayer structure interposed between the pair of electrodes. The device can include one or more light emitting layers each having an emission interface. In the device, there can be adjacent layers having an interfacial plane therebetween. The interfacial plane being disposed in a position where an optical path length from the emission interface to the interfacial plane is substantially equal to, or less than, the coherent length of light emitted from the emission interface. Furthermore, the difference in refractive index between the adjacent layers is substantially equal to, or less than, 0.6. This can eliminate an interference effect within the thin film multilayer structure, thereby enhancing light emitting efficiency and achieving intended light color.

This application claims the priority benefit under 35 U.S.C. §119 of Japanese Patent Application No. 2004-257169 filed on Sep. 3, 2004, Japanese Patent application No. 2004-349769 filed on Dec. 2, 2004 and Japanese Patent application No. 2005-091894 filed on Mar. 28, 2005, which are all hereby incorporated in their entirety by reference.

### BACKGROUND OF THE INVENTION

1. Field of the Invention

The invention relates to a light emitting diode device which is configured to emit light by injecting electrons and holes into a light emitting diode material being formed into a thin film, and causing recombination of the electrons and the holes therein. This phenomenon is also referred to as injection electroluminescence (EL).

2. Background of the Related Art

An organic light emitting diode (OLED) device (or organic electroluminescent device) is a self-luminous display device configured to convert electric energy into light energy by applying an electric current to an organic light emitting layer. Research and development of OLED devices have been actively pursued in recent years. Among these OLED devices, research and development has actively promoted, in particular, for an OLED device provided with an organic hole transport layer made of aromatic diamine and an organic light emitting layer made of an aluminum complex of 8-hydroxyquinoline (see Applied Physics Letters (1987) Vol. 51, p. 913, for example). One of the reasons for attention to this OLED device is that the OLED device can improve luminous efficiency as compared to other light emitting diode devices which use anthracene and the like.

FIG. 1 shows a typical structure of an OLED device. A transparent electrode layer (an anode) 1 is provided on a transparent substrate 2, and an organic material layer 3 (including a hole transport layer 4 and an organic light emitting layer 5) and a cathode layer (a cathode) 6 are further formed thereon in this order by the vacuum deposition method. When a direct-current voltage is applied between the transparent electrode layer 1 functioning as the anode and the cathode layer 6, holes injected from the transparent electrode layer 1 and electrons injected from the cathode layer 6 reach the hole transport layer 4 and the organic light emitting layer 5, respectively, and the electrons and the holes are recombined. At that time, the electric energy is converted into light energy, whereby light is emitted from the organic light emitting layer 5.

In this typical OLED device, the organic material layer 3 provided between the anode 1 and the cathode 6 is formed into a two-layer structure including the hole transport layer 4 and the organic light emitting layer 5 in order from the anode side. However, the organic material layer 3 may also be formed in other multilayer structures including, a hole injection layer/a hole transport layer/an organic light emitting layer/an electron transport layer, a hole injection layer/a hole transport layer/an organic light emitting layer, a hole transport layer/an organic light emitting layer/an electron transport layer, and the like. Moreover, the organic light emitting layer 5 may be formed in a multilayer structure independently.

The hole transport layer 4 may function to promote injection of the holes from the anode 1 and to block the electrons. Meanwhile, the electron injection layer may function to promote injection of the electrons from the cathode.

Metal having a large work function, and alloys as well as compounds thereof may be used as the material for forming the anode layer 1. For example, the applicable materials include Ni, Au, Pt, Pd, and alloys thereof, SnO₂, CuI, conductive polymers such as polypyrrole, and so forth. However, a transparent electrode layer made of, for example, ITO is generally used therefore.

Metal having a small work function (a low work function metallic material) may be used to form the cathode layer 6 in order to improve electron injection efficiency. The cathode layer 6 may be for instance formed by use of Al, Mg, an Mg—In alloy, an Mg—Al alloy, an Mg—Ag alloy, an Al—Li alloy, and the like in accordance with a dry process such as the vacuum deposition method, the sputtering method, etc.

As for the organic material layer 3 formed by use of an organic material, attempts to use a low molecular weight material such as tris(8-hydroxyquinolinato)aluminum (hereinafter abbreviated as Alq₃) or N,N′-diphenyl-N,N′-bis(3-methylphenyl)-1,1′-biphenyl-4,4′-diamine (hereinafter abbreviated as TPD) and to use a high molecular weight material such as polyparaphenylenevinylene (PPV) are currently in progress. Research and development for achieving higher luminance and more color variation with these materials have been actively pursued, and some products are being put into practical use.

In terms of the OLED device having the above-described structure, the light emitted from the transparent substrate 2 to the outside (to the atmosphere) can be emitted according to the following schemes, for example: (1) the light being emitted from the organic light emitting layer 5 toward the transparent electrode layer 1 and outgoing through the transparent electrode layer 1 and the transparent substrate 2; (2) the light being emitted from the organic light emitting layer 5 toward the cathode layer 6, reflected on the surface of the cathode layer 6, and outgoing through the transparent electrode layer 1 and the transparent substrate 2; and (3) the light being emitted from the organic light emitting layer 5, repeating reflection and refraction on respective interfaces of the transparent substrate 2, the transparent electrode layer 1, and the organic material layer 3 having the multilayer structure (including the hole transport layer 4 and the organic light emitting layer 5), and then outgoing from the transparent substrate 2. The respective beams of light have different optical path lengths from emission from the organic light emitting layer 5 to emission to the outside through the transparent substrate 2. Such differences in the optical path lengths may affect an output characteristic.

In this regard, there has been disclosed a technique configured to form the organic material layer 3 of an OLED device excluding the organic light emitting layer 5 by using a plurality of layers having different film thicknesses depending on luminescent colors in order to improve light extraction efficiency in terms of the respective colors by utilizing a reflection interference phenomena attributed to the plurality of layers.

For example, take the case where an electron transport layer (not shown in the figure) is provided in an OLED device and interposed between the organic light emitting layer 5 and the cathode layer 6. In this case, the film thickness of the hole transport layer 4 (for example, including a hole injection layer and a hole transport layer) interposed between the organic light emitting layer 5 and the anode layer 1, and the film thickness of the electron transport layer (for example, including an electron injection layer and an electron transport layer) interposed between the organic light emitting layer 5 and the cathode layer 6 are controlled. In the case of a structure shown in FIG. 2, the hole transport layer 4 is formed such that an optical path length ((n_{urg}·d_{org})+(n_{ITo}·d_{ITO})) from an emission interface 7 of the organic light emitting layer 5 to an interfacial plane between the transparent electrode layer 1 and the transparent substrate 2 is approximately equal to the product of ¼ of a desired peak emission wavelength λₚ and an even number. Here, n_{org} is a refractive index of the organic material layer 3, d_{org} is a film thickness of the hole transport layer 4, n_{ITO} is a refractive index of the transparent electrode layer 1, and d_{ITO} is a film thickness of the transparent electrode layer 1. In this way, the light emitted from the organic light emitting layer 5 toward the transparent electrode layer 1, which is internally reflected by the interfacial plane between the transparent electrode layer 1 and the transparent substrate 2 and thereby goes back to the emission interface 7, and the immediately emitted light interfere with and intensify each other to maximize the brightness.

In the meantime, the organic light emitting layer 5 is formed such that an optical path length (n_{org}·d₀) from the emission interface 7 to the cathode layer 6 is approximately equal to the product of ¼ of the desired peak emission wavelength λₚ and an odd number. Here, d₀ is a film thickness of the organic light emitting layer 5. In this way, the light emitted from the organic light emitting layer 5 toward the cathode layer 6, which is reflected by the surface of the cathode layer 6 and thereby goes back to the emission interface 7, and the immediately emitted light interfere with and intensify each other to maximize the brightness (see Applied Physics Letters (1987) Vol. 51, p. 913, for example).

Meanwhile, there is also disclosed a technique configured to obtain emitted light having a desired peak wavelength by controlling optical path lengths of the transparent electrode and the organic material layer (the hole transport layer and the organic light emitting layer) similarly (see Japanese Patent No. 2846571 and Japanese Patent Laid-Open Publication No. 2003-142277, for example).

However, it is difficult and sometimes not possible to control the interference between the light emitted from the emission interface toward the cathode, which is reflected by the surface of the cathode and thereby goes back to the emission interface, and the immediately emitted light merely by controlling the film thickness of the transparent electrode layer.

Moreover, the original purpose of controlling the film thickness of the organic material layer is to improve efficiency of transport and recombination of injected carriers, and to improve luminous efficiency in light of an emission mechanism thereof. Accordingly, if the film thickness control is focused only on the interference phenomena, the luminous efficiency may be degraded by deterioration in a voltage-luminance characteristic, for example.

In addition, there is known another configuration of an OLED device of an MPE structure. The MPE structure is a structure in which an organic material layer interposed between a pair of opposed electrodes includes a plurality of light emission units each having at least one light emitting layer, and the respective light emission units are partitioned by at least one layer composed of a charge generating layer. Accordingly, the MPE structure is configured to locate a plurality of light emitting positions separately from one another. In terms of this structure, there is disclosed a technique for achieving high luminous efficiency by setting all optical film thicknesses from the respective light emitting positions to a light reflection electrode approximately equal to the products of a ¼ wavelength and odd numbers (see Japanese Patent Laid-Open Publications Nos. 2003-272860 and 2003-45676, for example).

In this case, however, the effect of interference becomes prominent due to a large total film thickness, and the effect is significantly cancelled out by just a small misalignment in the film thickness control. As a result, distribution of an emission spectrum changes and the change causes a color tone shift and reduction in the luminous efficiency. Accordingly, the optical film thicknesses from the respective light emitting positions to the light reflection electrode need to be controlled very strictly. In this OLED device structure as well, it is indispensable to set up the appropriate film thicknesses so as to improve the efficiency of transport and recombination of injected carriers, and to improve the luminous efficiency. Therefore, it is extremely difficult to set up the film thicknesses appropriately to meet both the requirements of the above-described efficiencies and the conditions of interference.

Even if the optical film thicknesses from the respective light emitting positions to the light reflection electrode were strictly controlled, a spectral half bandwidth is reduced while the peak emission wavelength is unchanged if the total film thickness becomes larger due to an increase in the number of the light emission units (the organic film structures each including at least one light emitting layer) that constitute the OLED device. Accordingly, the distribution of the emission spectrum originally possessed by the luminescent material may be deviated. In addition, the color tone of light may differ depending on the viewing angle of the OLED device.

Incidentally, it is inappropriate under present circumstances to apply film thickness settings for a usual OLED device (the OLED device having a single light emission unit unlike the MPE structure) to obtain the optimal carrier balance in terms of the efficiency of transport and recombination of injected carriers and the luminous efficiency directly to the MPE structure. Therefore, the MPE configuration is set up while giving up its optical and electric characteristics to some extent. Meanwhile, adjacent light emitting portions will hold a plurality of target wavelengths when laminating an OLED device including a plurality of light emitting portions in a single light emission unit (such as a device configured to emit white light by additive color mixing of blue-emitting light and orange-emitting light). In this case, it is difficult just to design such a device which can realize light emission of a desired color tone.

As methods of suppressing the interference effect without requiring the above-described strict film thickness control, there have been proposed a technique configured to blacken and convert a cathode previously functioning as a light reflective electrode into a non-reflective electrode, and a technique configured to allow at least one layer located between a light emitting layer and a cathode to function as a light absorption layer. However, these methods cannot utilize the internally reflected light of the OLED device. Accordingly, these methods can only achieve an OLED device having lower luminance as compared to a conventional OLED device.

In the meantime, an OLED device having a structure as shown in FIG. 3 has been proposed in recent years. Both an anode 1 and a cathode 6 of this device are formed into transparent electrodes, whereby this device is intended to realize a light emission device of a see-through type, which is capable of extracting light emitted from an organic light emitting layer 5 from both surfaces of the device, and of seeing the other side through the device when the light is not emitted (see Japanese Patent Laid-Open Publications Nos. Hei 10(1998)-162959 and 2002-289362, for example).

Although the inventions disclosed in these publications may realize the double-sided emission and see-through type OLED device, this structure causes different color tones of the light emitted from the respective two surfaces of the device upon light emission. This structure leads to a large difference of the refractive index between the transparent electrode layer as the cathode and the atmosphere (the air), and an interfacial plane thereof functions as a reflection surface. For this reason, the light emitted from a transparent substrate on the anode side to the atmosphere is affected by interference. This interference is caused by a difference in the optical path length between light being emitted from an emission interface toward the cathode, reflected by the interfacial plane between the transparent layer of the cathode and the atmosphere, and then heading for the anode side, and light emitted from the emission interface toward the anode.

In terms of the structure of the conventional OLED device of the single-sided emission type using an opaque material such as Al on or with the cathode, there has been proposed a method of controlling the color tone of the emitted light by appropriately setting up the film thicknesses of the transparent electrode and the organic material layer so as to suppress the influence of interference.

However, in this case as well, the voltage-luminance characteristic is deteriorated by controlling the film thicknesses only in light of suppression of the interference phenomena, and the light extraction efficiency to the outside is degraded as a consequence.

Even if suppression of the influence of interference with the light emitted from the device is attempted by controlling the film thicknesses of the transparent electrode and the organic material layer, it will remain an extremely difficult task to set up the film thicknesses of the transparent electrodes and the organic material layer of the double-sided emission device so as to control the color tones of the light emitted from the respective surfaces individually.

Moreover, in terms of the above-described OLED device of the MPE structure as disclosed in Japanese Patent Laid-Open Publication No. 2003-272860, it is possible to realize a double-sided emission and see-through type device by providing a pair of transparent electrodes. However, the interference effect is remarkable in this case due to the large total film thickness. For this reason, the color tone shift between the light emitted from respective surfaces is further intensified, and it is even more difficult to align the color tones of the light emitted from the two surfaces only by controlling the film thicknesses of the transparent electrodes and the organic material layers.

### SUMMARY OF THE INVENTION

The invention has been accomplished in consideration of the foregoing and other various problems and challenges in the art of light emitting diodes. In accordance with one of the many aspects of the invention, an LED device can be provided that permits efficient extraction of light to the outside while eliminating an effect of interference, by means of effectively utilizing light, which is emitted from an emission interface of a light emitting layer and is reflected inside the LED device, and avoiding the light from constituting a trigger for the interference.

In accordance with another aspect of the invention, an LED device can be a double-sided emission type while eliminating an effect of interference. In other words, an LED device can have enhanced light extraction efficiency with an attempt to optimize carrier transport, recombination, and light emission. One way that such an LED device can be achieved is by eliminating a difference in the color tone of the light emitted from respective surfaces to the outside as a result of a configuration to emit the light having an emission spectrum unique to a luminescent material constituting a light emitting layer from the respective surfaces to the outside, and by allowing settings of film thicknesses of respective layers constituting the device without considering the effect of interference.

Another of the aspects of the invention is a light emitting diode (LED) device that includes a pair of opposed electrodes; and a thin film multilayer structure interposed between the pair of electrodes and including at least one light emitting layer, the light emitting layer having an emission interface. The LED device can have adjacent layers having an interfacial plane therebetween which is disposed in a position where an optical path length from the emission interface to the interfacial plane is equal to, or less than, a coherent length of light emitted from the emission interface. Here, a difference in refractive index between the adjacent layers excluding the reflecting mirror is equal to, or less than, 0.6.

The LED device according to the above aspect can include a reflecting mirror which is disposed in a position where an optical path length from the emission interface to the reflecting mirror is set to a value equal to, or more than, the coherent length of light emitted from the emission interface.

In the LED device according to the above aspect, the pair of the electrodes may be transparent electrodes. In this case, the reflecting mirror may be arranged to be in contact with an outer surface of one of the transparent electrodes or to be disposed in a position outside the one of the transparent electrodes with provision of a certain distance from the transparent electrode such that the reflection mirror is opposed to the transparent electrode.

The LED device according to the above aspect can include a buffer layer disposed outside one of the transparent electrodes and/or between one of the transparent electrodes and the reflecting mirror.

In the LED device according to the above aspect, the buffer layer may be formed into a vacuum or formed of one selected from the group consisting of a transparent material and a gas.

In the LED device according to the above aspect, one of the pair of electrodes may be a transparent electrode and the other electrode may be a reflecting electrode serving as the reflecting mirror.

In the LED device having the buffer layer according to the above aspect, the pair of the electrodes can be transparent electrodes, the buffer layers can be formed outside the pair of transparent electrodes, respectively, and the coherent length of the light emitted from the emission interface positioned within the buffer layers.

In the LED device according to the above aspect, the thin film multilayer structure may be composed of a plurality of light emitting units each having at least one light emitting layer, and a charge generating layer can be formed between the light emitting units.

Another aspect of the invention is also an LED device. The LED device can include a pair of opposed electrodes, a thin film multilayer structure interposed between the pair of electrodes and including at least one light emitting layer, the light emitting layer including an emission interface, and a reflecting mirror which is disposed in a position where an optical path length from the emission interface to the reflecting mirror is set to a value equal to, or more than, a coherent length of light emitted from the emission interface. The LED device can have adjacent layers having an interfacial plane therebetween which is disposed in a position where an optical path length from the emission interface to the interfacial plane is equal to, or less than, the coherent length of light emitted from the emission interface. In this LED device, a difference in refractive index between the adjacent layers excluding the reflecting mirror is equal to, or less than, 0.6.

In the LED device according to the above aspect, the pair of electrodes may be transparent electrodes. In this case, the reflecting mirror may be arranged to be in contact with an outer surface of one of the transparent electrodes or disposed in a position outside the one of the transparent electrodes with provision of a certain distance from the transparent electrode such that the reflection mirror is opposed to the transparent electrode.

The LED device according to the above aspect can include a buffer layer disposed outside one of the transparent electrodes and/or between the one of the transparent electrodes and the reflecting mirror.

In the LED device according to the above aspect, the buffer layer may be formed into a vacuum or formed of one selected from the group consisting of a transparent material and a gas.

In the LED device according to the above aspect, one of the pair of electrodes may be a transparent electrode and the other electrode may be a reflecting electrode serving as the reflecting mirror.

In the LED device having the buffer layer according to the above aspect, the thin film multilayer structure may be composed of a plurality of light emitting units each having at least one light emitting layer, and a charge generating layer formed between the light emitting units.

Still another aspect of the invention is also an LED device. The LED device can include a pair of opposed transparent electrodes, and a thin film multilayer structure interposed between the pair of electrodes and including at least one light emitting layer, the light emitting layer including an emission interface. The LED device can have adjacent layers having an interfacial plane therebetween which is disposed in a position where an optical path length from the emission interface to the interfacial plane is equal to, or less than, the coherent length of light emitted from the emission interface. In this LED device, a difference in refractive index between the adjacent layers excluding the reflecting mirror is equal to, or less than, 0.6.

The LED device according to the above aspect can include buffer regions disposed outside the pair of transparent electrodes, respectively. In this LED device, the coherent length of the light emitted from the emission interface may be positioned within the buffer regions.

Still another aspect of the invention is an LED device that can include a thin film multilayer structure having a transparent substrate, a first transparent electrode, a plurality of organic material layer including a light emitting layer having an emission interface, and a second transparent electrode in this order, and further having a transparent buffer layer disposed outside the second transparent electrode and including a transparent material. In this LED device, an optical path length from the emission interface to an outer surface of the transparent substrate and an optical path length from the emission interface to the outside of the transparent buffer layer is equal to, or more than, a coherent length of light emitted from the emission interface. A difference in refractive index between the transparent substrate and the first transparent electrode and a difference in refractive index between the transparent buffer layer and the second transparent electrode are equal to, or less than, 0.6.

Still another aspect of the invention is an LED device that can include a thin film multilayer structure having a transparent substrate, a first transparent electrode, a plurality of organic material layer including a light emitting layer having an emission interface, and a second transparent electrode in this order, and further having a first transparent buffer layer disposed between the transparent substrate and the first transparent electrode and a second transparent buffer layer disposed outside the second transparent electrode. In the LED device, an optical path length from the emission interface to an interfacial plane between the transparent substrate and the first transparent buffer layer and an optical path length from the emission interface to the outside of the second transparent buffer layer are equal to, or more than, a coherent length of light emitted from the emission interface. Further, in the LED device a difference in refractive index between the first transparent buffer layer and the first transparent electrode and a difference in refractive index between the second transparent buffer layer and the second transparent electrode are equal to, or less than, 0.6.

Still another aspect of the invention is an LED device that can include a thin film multilayer structure having a transparent substrate, a first transparent electrode, a plurality of organic material layer including a light emitting layer having an emission interface, and a second transparent electrode in this order. In this LED device, a sealing transparent substrate can be disposed near the second transparent electrode to be opposed to the second transparent electrode and a transparent material can be filled in between the second transparent electrode and the sealing transparent substrate. Here, an optical path length from the emission interface to an outer surface of the transparent substrate and an optical path length from the emission interface to an interfacial plane between the transparent material and the sealing transparent substrate are equal to, or more than, a coherent length of light emitted from the emission interface. Furthermore, in the LED device, a difference in refractive index between the transparent substrate and the first transparent electrode, a difference in refractive index between the sealing transparent substrate and the transparent material, and a difference in refractive index between the transparent material and the second transparent electrode are equal to, or less than, 0.6.

Still another aspect of the invention is an LED device that can include a thin film multilayer structure having a transparent substrate, a first transparent electrode, a plurality of thin film layer including a light emitting layer having an emission interface, and a second transparent electrode in this order, and further having a transparent buffer layer disposed between the transparent substrate and the first transparent electrode, a sealing transparent substrate disposed near the second transparent electrode to be opposed to the second transparent electrode, and a transparent material layer disposed between the second transparent electrode and the sealing transparent substrate. In this LED device, an optical path length from the emission interface to an interfacial plane between the transparent substrate and the transparent buffer layer and an optical path length from the emission interface to an interfacial plane between the transparent material layer and the sealing transparent substrate are equal to, or more than, a coherent length of light emitted from the emission interface. Furthermore, in the LED device, a difference in refractive index between the transparent buffer layer and the first transparent electrode, and a difference in refractive index between the transparent material layer and the second transparent electrode are equal to, or less than, 0.6.

Still another aspect of the invention is an LED device that can include a pair of opposed transparent electrodes, and a thin film multilayer structure interposed between the pair of transparent electrodes and including an organic material layer which is composed of a plurality of light emitting units each having at least one light emitting layer including an emission interface and at least one charge generating layer partitioning the light emitting units. The LED device can have adjacent layers having an interfacial plane therebetween which is disposed in a position where an optical path length from the emission interface to the interfacial plane is equal to, or less than, a coherent length of light emitted from the emission interface. Here, a difference in refractive index between the adjacent layers is equal to, or less than, 0.6.

The LED device according to the above aspect can further include buffer regions disposed outside the pair of transparent electrodes, respectively. In this case, the coherent length of the light emitted from the emission interface may be positioned within the buffer regions.

In the LED device having the above-described configuration, the light emitted from the emission interface of the light emitting layer and reflected inside the LED device does not constitute the trigger for the interference. Moreover, it is possible to effectively utilize the light emitted from the emission interface of the light emitting layer and reflected inside the LED device, and to extract the light efficiently to the outside while eliminating the effect of the interference.

Meanwhile, it is not necessary to consider the effect of the interference when setting up the film thicknesses of the respective layers constituting the device. Accordingly, it is possible to set up the film thicknesses with particular emphasis on the efficiency of transport and recombination of carriers, the luminous efficiency, and the like. In this way, it is possible to optimize the film thicknesses.

Here, distribution of the emission spectrum does not change along with the changes in the film thicknesses. Accordingly, it is possible to avoid a change in the color tone of the emitted light.

Meanwhile, the distribution of the emission spectrum hardly changes along with a change in the viewing angle to an emission surface of the LED device. Accordingly, the change in the color tone of the emitted light is not observed from any viewing angle.

In addition, a double-sided emission type LED device of another aspect can eliminate the effect of interference with the light emitted from the respective sides. Here, it is possible to align a color tone of the light emitted from an emission interface of the light emitting layer substantially with the color tone of the light emitted from each side. Similarly, it is possible to align the color tones of the light emitted from the respective sides substantially with each other.

In addition, a double-sided emission type LED device of another different aspect including a plurality of separately located light emitting positions have similar effects to the foregoing.

### BRIEF DESCRIPTION OF THE DRAWINGS

These and other aspects and advantages of the invention will become clear from the following description with reference to the accompanying drawings, wherein:

FIG. 1 is a schematic structural drawing of a typical OLED device;

FIG. 2 is a schematic structural drawing of another typical OLED device;

FIG. 3 is a schematic structural drawing of still another typical OLED device;

FIG. 4 is a schematic cross-sectional view showing an OLED device according to an embodiment of the invention;

FIG. 5 is a waveform chart showing a damped oscillation of a light wave emitted from a luminescent body;

FIG. 6 is a graph showing a photoluminescent (PL) spectrum of Alq₃;

FIG. 7 is a schematic cross-sectional view showing an OLED device according to another embodiment of the invention;

FIG. 8 is a graph showing a PL spectrum of a blue light-emitting material (referred to also as a blue light-emitting dopant hereinafter);

FIG. 9 is a graph showing PL spectra in Comparative Examples 1 to 3;

FIG. 10 is a graph showing a PL spectrum in Example 1;

FIG. 11 is a graph showing a PL spectrum in Example 4;

FIG. 12 is a graph showing a PL spectrum in Example 6;

FIG. 13 is a graph showing a PL spectrum in Example 9;

FIG. 14 is a graph showing a modulation spectrum in Example 1;

FIG. 15 is a graph showing relationships between optical path lengths from an emission interface to a reflecting mirror and degrees of modulation in Examples 1 to 9 and Comparative Example 2;

FIG. 16 is a graph showing relationships between optical path lengths from an emission interface to a reflecting mirror and chromaticity coordinates (x) of emitted light in Examples 1 to 9 and Comparative Examples 1 to 4;

FIG. 17 is a graph showing relationships between the optical path lengths from the emission interface to the reflecting mirror and chromaticity coordinates (y) of the emitted light in Examples 1 to 9 and Comparative Examples 1 to 4;

FIG. 18 is a graph showing PL spectra of green light-emitting and red light-emitting materials (referred to also as a green light-emitting dopant and a red light-emitting dopant, hereinafter);

FIG. 19 is a graph showing PL spectra in Example 10 and Comparative Example 4;

FIG. 20 is a graph showing PL spectra in Examples 11 and 12;

FIG. 21 is a graph showing a PL spectrum in Comparative Example 5;

FIG. 22 is a graph showing a PL spectrum in Example 13;

FIG. 23 is a graph showing a PL spectrum of a yellow light-emitting material (referred to also as a yellow light-emitting dopant hereinafter);

FIG. 24 is a graph showing PL spectra in Example 14 and Comparative Example 4;

FIG. 25 is a graph showing relationships between differences of refractive indices and chromaticity coordinates of outgoing light in Examples 14 to 17 and Comparative Example 4;

FIG. 26 is a graph showing PL spectra in Example 18 and Comparative Example 6;

FIG. 27 is a graph showing relationships between gaps of refractive indices and chromaticity coordinates of outgoing light in Examples 18 to 20 and Comparative Example 6;

FIG. 28 is a schematic cross-sectional view showing an OLED device according to still another embodiment of the invention;

FIG. 29 is a graph showing respective PL spectra of OLED devices of three different configurations;

FIG. 30 is a schematic cross-sectional view showing an OLED device according to still another embodiment of the invention;

FIG. 31 is a schematic cross-sectional view showing an OLED device according to still another embodiment of the invention;

FIG. 32 is a graph showing a PL spectrum of a yellow light-emitting dopant;

FIG. 33 is a graph showing a PL spectrum of a yellow light-emitting dopant in Comparative Example 7;

FIG. 34 is a graph showing a PL spectrum of a blue light-emitting dopant in Example 21;

FIG. 35 is a graph showing relationships between differences of refractive indices and chromaticity coordinates of outgoing light in Examples 21 to 24 and Comparative Example 7;

FIG. 36 is a graph showing PL spectra in Comparative Example 8 and of a yellow light-emitting dopant;

FIG. 37 is a graph showing PL spectra in Example 25 and of a yellow light-emitting dopant;

FIG. 38 is a graph showing relationships between differences of refractive indices and chromaticity coordinates of outgoing light in Examples 25 to 27 and Comparative Example 8;

FIG. 39 is a graph showing a PL spectrum in Comparative Example 9; and

FIG. 40 is a graph showing a PL spectrum in Example 28;

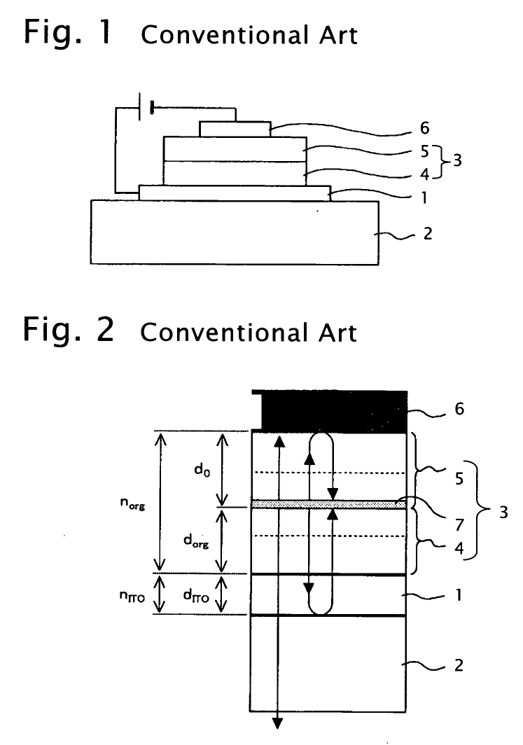

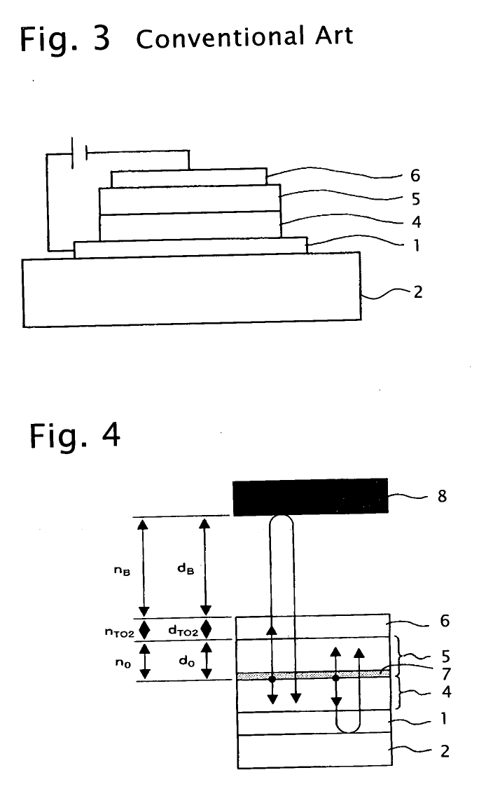

### DETAILED DESCRIPTION OF PREFERRED EMBODIMENTS

Now, embodiments of the invention will be described in detail with reference to the accompanying drawings of FIG. 4 to FIG. 40. Note that the invention is not limited only to the embodiments illustrated in the drawings. Although the embodiments will be described on the basis of an organic light emitting diode (OLED) device as an example, the invention is not limited only to the OLED device, and is also applicable to an inorganic light emitting diode device as long as such an inorganic LED device includes a thin film lamination structure between both electrodes.

In the drawings, the same components in the embodiments of the invention as in the conventional art will be denoted by the same reference numerals and the description thereof will be omitted in some cases.

FIG. 4 is a cross-sectional view showing a structure of an OLED device according to an embodiment of the invention. A first transparent electrode layer (an anode) 1, a hole transport layer 4, an organic light emitting layer 5, and a second transparent electrode layer (a cathode) 6 are sequentially formed on a transparent substrate 2. Moreover, a reflecting mirror 8 is disposed in a position outside the second transparent electrode layer (the cathode) 6 with provision of a certain length from the second transparent electrode layer 6, such that a reflection surface thereof is opposed to the second transparent electrode layer 6.

The position where the reflecting mirror 8 is located is adjusted such that an optical path length from an emission interface 7 of the organic light emitting layer 5 to the reflecting mirror 8 is equal to, or more than, “a coherent length of light emitted from the light emitting layer”. In this specification, the term “coherent length” will be defined as follows.

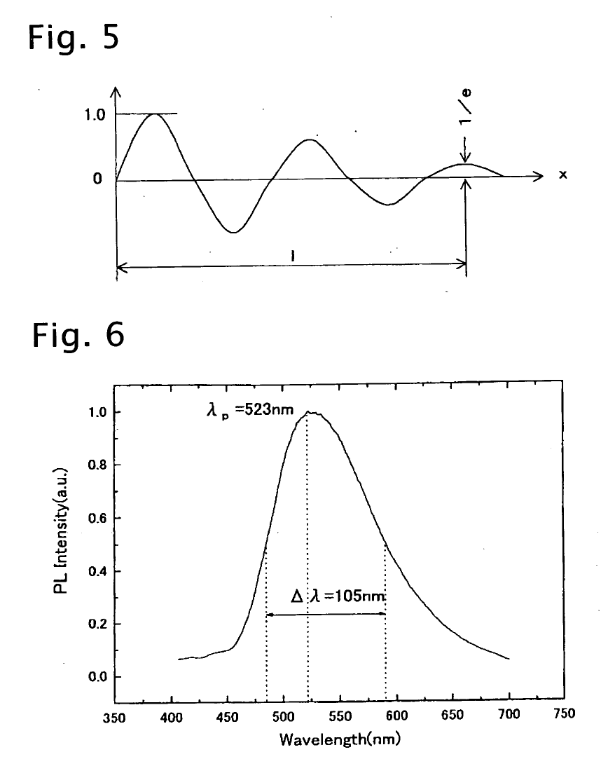

A light wave emitted from a luminescent body exhibits an aspect of a damped oscillation as shown in FIG. 5. In this case, an effective range of the light wave is deemed to have a finite length l where an amplitude is equal to l/e (e is the base of natural logarithm) of an initial value.

After emitting this wave, the luminescent body subsequently emits the next wave having the same frequency. However, the precedent wave and the subsequent wave have different phases. Therefore, even when superposing the two waves emitted from the same light source, wave fronts having different phase will be superposed when a difference in the optical path length between optical paths of the respective waves exceeds l. In this case, an interference phenomenon does not occur.

Utilizing this principle, the invention can eliminate an interference influence in terms of an optical system ranging from emission of the light from a light emitting layer to emission of the light to the outside. As described above, the coherent length of light corresponds to the finite length l of a wave shown in FIG. 5. The coherent length is generally expressed by the following relational expression:
Lc=λₚ²/Δλ (1)
in which Lc is the coherent length, λₚ is a peak wavelength of an emission spectrum, and Δλ is a spectral half bandwidth.

A conventional OLED device would cause interference between light emitted from an emission interface toward a cathode, which is reflected by the surface of the cathode and thereby goes back toward an anode, and light emitted from the emission interface toward the anode, for example. A difference between optical paths of the respective light beams is equal to two times the optical path length from the emission interface to the reflection surface of the cathode. Therefore, the interference does not occur if this difference in the optical path length is greater than the coherent length Lc. In other words, it seems possible to suppress the influence of interference when the optical path length from the emission interface to the reflection surface of the cathode is greater than Lc/2.

However, even when the optical path length from the emission interface to the reflection surface of the cathode is set greater than Lc/2 in the actual OLED device, it turns out that the chromaticity is shifted due to imperfect film thickness setting in spite of some reduction in the influence of interference. Accordingly, it may be preferable to set the optical path length from the emission interface to the reflection surface of the cathode equal to, or more than, the coherent length Lc in order to completely suppress the influence of interference with the chromaticity and the like.

Upon calculation of the coherent length Lc of the emitted light in terms of the OLED device, the peak wavelength λₚ of the emitted light and the spectral half bandwidth Δλ used in the foregoing relational expression can be read out of a photoluminescent (PL) spectrum of the light emitting layer.

For example, a coherent length of Alq₃ (λₚ=523 nm, Δλ=105 nm) having a PL spectrum as shown in FIG. 6 is equal to 2605 nm by use of the foregoing relational expression. Therefore, when forming the light emitting layer of the OLED device of the invention shown in FIG. 4 by use of Alq₃, the optical path length from the emission interface to the reflecting mirror should be set equal to, or more than, 2605 nm.

Meanwhile, in this case, a film thickness of each of the layers located between the emission interface and the reflecting mirror is set to satisfy the following relational expression (2):
Lc≦d₀·n₀+d_{TO2}·n_{TO2}+d_{B}·n_{B} (2)
in which do is a film thickness of the organic light emitting layer 5, n₀ is a refractive index of the organic light emitting layer 5, d_{TO2} is a film thickness of the second transparent electrode layer (cathode) 6, n_{TO2} is a refractive index of the second transparent electrode layer (cathode) 6, d_{B} is a distance between the second transparent electrode layer (cathode) 6 and the reflecting mirror 8, and n_{B} is a refractive index of a material with which the space between the second transparent electrode layer (cathode) 6 and the reflecting mirror 8 is filled.

Here, the optical path length from the emission interface to the reflecting mirror does not have a particular upper limit. However, it is recommended to set the optical path length equal to, or less than, 1000 μm in order not to lose a thin profile advantage of the OLED device. On the contrary, a lower limit of the optical path length can be set equal to, or more than, the coherent length Lc, or equal to about two times the Lc value in order to completely eliminate the influence of interference. While an emission region presumably has a certain width inside the light emitting layer, a given position assumed to have high emission intensity will be defined as the emission interface in the invention. For example, in the structure including the hole transport layer 4 and the organic light emitting layer 5 as shown in FIG. 4, the emission intensity presumably reaches the maximum in a region adjacent to the hole transport layer 4 in the organic light emitting layer 5. Accordingly, it is possible to regard the interface of these two layers as the emission interface 7.

When the single light emitting layer is made of two or more kinds of luminescent materials, the longest of the coherent lengths calculated by use of PL spectra of the respective materials will be applied.

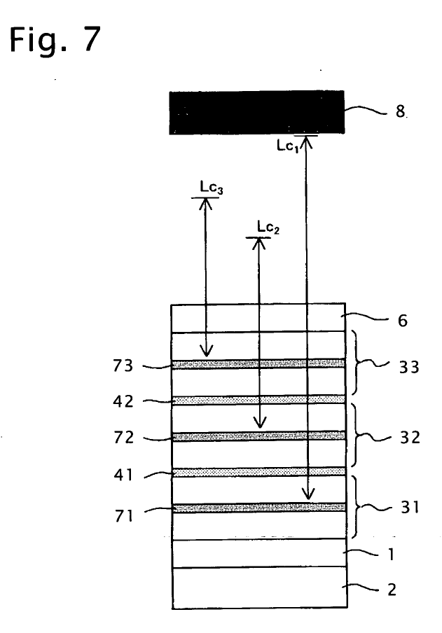

FIG. 7 is a cross-sectional view showing a structure of an OLED device according to another embodiment of the invention. In this embodiment an MPE structure is employed, (a structure in which an organic material layer being interposed between a pair of opposed electrodes includes a plurality of light emission units each having at least one light emitting layer, and the respective light emission units are partitioned by at least one layer of a charge generating layer). The MPE structure is configured to locate a plurality of light emitting positions separately from one another.

Here, the light emission unit means an element which includes a layer structure including at least one light emitting layer mainly made of an organic compound and excludes an anode and a cathode out of constituents of a typical OLED device. Meanwhile, the charge generating layer includes a transparent conductive material such as ITO (indium tin oxide), IZO (indium zinc oxide), SnO₂ or ZnO₂, a hole transport material such as V₂O₅ or 4F-TCNQ (tetracyanoquinodimethane) to be formed thereon, and a substance which can form a charge transfer complex by an oxidation-reduction reaction. The charge generating layer can function to inject holes into a light emission unit adjacent to a cathode thereof, and to inject electrons into a light emission unit adjacent to an anode thereof.

As for the concrete structure of the OLED device shown in FIG. 7, a first transparent electrode layer (an anode) 1 is formed on a transparent substrate 2. Then, a first light emission unit 31 including a first emission interface 71, a first charge generating layer 41, a second light emission unit 32 including a second emission interface 72, a second charge generating layer 42, a third light emission unit 33 including a third emission interface 73, and a second transparent electrode layer (a cathode) 6 are sequentially formed thereon. Moreover, a reflecting mirror 8 is disposed in a position outside the second transparent electrode layer (the cathode) 6 with provision of a certain distance from the second transparent electrode layer 6, such that the reflection surface thereof is opposed to the second transparent electrode layer 6.

To dispose the reflecting mirror 8 so as to avoid the interference of the light emitted from the respective emission interfaces 71, 72, 73 of these three light emission units 31, 32, 33 in the OLED device structured as described above, the positions of the respective layers are set up as follows. The respective coherent lengths are derived from the PL spectra of the light emitted from the emission interfaces of the respective light emission units by use of the aforementioned relational expression (1). Next, the farthest position from the second transparent electrode layer is selected from the positions of the coherent lengths away from the respective emission interfaces. As a result, since a position Lc₁ is located in the farthest position from the second transparent electrode layer 6 as shown in FIG. 7, the reflecting mirror 8 is disposed either in this position or in a position still farther from the second transparent electrode layer 6 than this position. In this way, it is possible to eliminate the influence of interference with the light emitted from the respective light emission units.

In the configurations shown in FIG. 4 and FIG. 7, the space between the second transparent electrode layer 6 and the reflecting mirror 8 may be formed into a vacuum, or filled with a gas or a liquid, etc. Meanwhile, it is also possible to form a transparent first buffer layer made of a translucent material on the second transparent electrode layer 6, and to form the reflecting mirror 8 by subjecting an upper surface of the transparent first buffer layer to metal deposition (not shown). Although the invention is not limited to the following features, it is sometimes preferable to use an inert gas such as dehumidified N₂ gas or Ar gas as the gas to be filled in these configurations. Meanwhile, dehydrated silicone oil or fluorine-containing oil is applicable to be used as the liquid therein. As the material of the transparent first buffer layer, it is possible to use metal oxides, nitrides, fluorides, other low molecular materials (such as TiO₂, SiO₂, SiNx, Ta₂O₅, SiO, Al₂O₃, ZrO₂, Sb₂O₃, TiO, and HfO₂), and high molecular materials such as transparent epoxy, acryl or nylon. The material used herein is not particularly limited as long as the material is transparent and capable of achieving a film thickness in the micrometer order.

In any case, the space between the second transparent electrode layer 6 and the reflecting mirror 8 may be formed as a vacuum or filled with the transparent material cited above, as long as the space satisfies the purpose to maintain the optical path length from the emission interface 7 to the reflecting mirror 8 equal to, or more than, the coherent length Lc.

It is to be noted, however, that a difference between the refractive index of the transparent material and the refractive index of the second transparent electrode layer 6 may lead to occurrence of the interference. This is attributable to the fact that when an interfacial plane is defined by two materials having different refractive indices, reflectivity of an incident ray becomes greater as the difference in the refractive index of these materials is greater. As a result, an optical path length of the light to the interfacial plane between the transparent material and the second transparent electrode layer 6 becomes shorter than the coherent length Lc, thereby the interference may occur. In addition, the reflectivity grows larger as the difference in the refractive index is greater, whereby larger interference may occur.

Accordingly, it is recommended to set the difference in the refractive index between the second transparent electrode layer 6 and the transparent material provided between the second transparent electrode layer 6 and the reflecting mirror 8 equal to, or less than, 0.6 to avoid occurrence of interference. It may be more effective to reduce interference if this difference is set as close to 0 as possible.

For example, in the embodiment shown in FIG. 4, interfacial planes located between the emission interface 7 and the reflecting mirror 8 include an interfacial plane between the organic material layers 4, 5, an interfacial plane between the organic material layers 4, 5 and the second transparent electrode layer 6, and an interfacial plane between the second transparent electrode layer 6 and the transparent material. These interfacial planes exist as reflective surfaces in the positions where the optical path lengths from the emission interface may become less than the coherent length Lc. Therefore, these interfacial planes may cause large interference along with an increase in the reflectivity.

Among these interfacial planes, the interfacial plane between the second transparent electrode layer 6 and the transparent material is likely to form the reflective surface having relatively large reflectivity. For example, when the space between the second transparent electrode layer 6 and the reflecting mirror 8 is formed into a vacuum or filled with a gas (having the refractive index of approximately 1.0), the difference in the refractive index between the transparent material and the material such as ITO, IZO, ZnO or SnO₂ used as the second transparent electrode layer 6 (having the refractive index of approximately 1.95) is approximately equal to 0.95. This reflective surface having the difference in the refractive index of 0.95 would merely cause a slight influence of interference when the optical path length from the emission interface 7 to the interfacial plane between the second transparent electrode layer 6 and the transparent material is set approximately equal to 300 nm.

On the contrary, the influence of interference will be remarkably large in the OLED device according to the different embodiment of the invention as shown in FIG. 7, which includes the plurality of light emitting positions located separately from one another and thereby requires a very long optical path length from the emission interface to the interfacial plane between the second transparent electrode layer 6 and the transparent material.

Therefore, in order to suppress occurrence of the interference, it is possible to select the materials for forming the second transparent electrode layer 6 and the transparent material appropriately in response to the optical path length from the emission interface to the interfacial plane between the second transparent electrode layer 6 and the transparent material, and thereby to adjust the difference in the refractive index between these materials.

In the case of the OLED device having the optical path length from the emission interface 7 to the interfacial plane between the second transparent electrode layer 6 and the transparent material approximately equal to 300 nm as shown in FIG. 4, it is possible to set the difference in the refractive index between the second transparent electrode layer 6 and the transparent material equal to, or less than, 0.6 in order to virtually suppress occurrence of the interference.

Meanwhile, in the case of the OLED device including the plurality of light emitting positions located separately from one another as shown in FIG. 7, the optical path length from the emission interface to the interfacial plane between the second transparent electrode layer 6 and the transparent material is increased along with an increase in the number of the light emission units each including at least one light emitting layer. Therefore, it is may be recommended to further reduce the difference in the refractive index between the second transparent electrode layer 6 and the transparent material in this case.

Next, the materials applicable to the reflecting mirror include: deposited films of either a simple substance or an alloy of Ag, Al, Au, Pt, W, Mg, Ni, Rh, and the like; and a multilayer mirror formed by alternately laminating two different types of oxide, nitride, and/or semiconductor layers. The combination examples in the latter case include: TiO₂ and SiO₂; SiNx and SiO₂; Ta₂O₅ and SiO₂; GaAs and GaInAs; and the like. In addition, it is also possible to select and combine materials having the different refractive indices from the group of SiO, Al₂O₃, ZrO₂, Sb₂O₃, TiO, HfO₂, Y₂O₃, MgO, CeO₂, Nb₂O₅, MgF, SrF₂, BaF₂, and the like as appropriate.

The interference phenomena concerning the light emitted from the emission interface toward the reflecting mirror in the OLED device have been reviewed from a variety of different angles. It is to be noted, however, that the light emitted from the emission interface toward the transparent substrate similarly concerns the interference phenomena.

In the structure of the OLED device shown in FIG. 4, there are an interfacial plane between the organic material layers 3, an interfacial plane between the organic material layer 3 and the first transparent electrode layer 1, and an interfacial plane between the first transparent electrode layer 1 and the transparent substrate 2 in the area between the emission interface 7 and the transparent substrate 2. There is a possibility that the optical path length from the emission interface 7 to each of the interfacial planes becomes less than the coherent length Lc. Accordingly, there is a possibility of occurrence of interference between light emitted from the emission interface 7 toward the transparent substrate 2 and reflected by any of these interfacial planes and light emitted from the emission interface toward the second transparent electrode layer 6. It is possible to suppress occurrence of the interface by reducing the difference in the refractive index between the respective materials of the layers constituting each of the interfacial planes as small as possible.

In particular, the interfacial plane between the first transparent electrode layer 1 and the transparent substrate 2 has the largest difference in the refractive index among these three interfacial planes. For example, in the case of using soda glass (having the refractive index of approximately 1.5) as the transparent substrate 2 and using a typical material such as ITO, IZO, ZnO or SnO₂ (having the refractive index of approximately 1.95) as the first transparent electrode layer 1, the difference in the refractive index is approximately equal to or above 0.4. This reflective surface having the difference in the refractive index of approximately 0.4 would hardly causes any influence of interference when the optical path length from the emission interface 7 to the transparent substrate 2 is set approximately equal to 400 nm. However, the influence of interference will be remarkably large in the OLED device according to the different embodiment of the invention as shown in FIG. 7, which includes the plurality of light emitting positions located separately from one another and thereby requires a very long optical path length from the emission interface to the transparent substrate 2.

Therefore, in order to suppress occurrence of the interference, it is possible to select the materials for forming the first transparent electrode layer 1 and the transparent substrate 2 appropriately in response to the optical path length from the emission interface to the transparent substrate 2, and thereby to adjust the difference in the refractive index between these materials.

In another aspect, a buffer layer having an extremely small difference in the refractive index relative to the first transparent electrode layer can be formed between the first transparent electrode layer and the transparent substrate in an appropriate film thickness so as to achieve the optical path length from the emission interface to the transparent substrate equal to or above the coherent length Lc of the light emitted from the light emitting layer. The materials similar to the above-described first buffer layer provided between the second transparent electrode layer and the reflecting mirror can be used as the material of this buffer layer. Meanwhile, although there is no particular limitation to the material of the transparent substrate having the very small difference in the refractive index relative to the first transparent electrode layer, examples of the material of the transparent substrate include LaSFN9 (made by Schott Glas AG) (having the refractive index of 1.85).

Here, the OLED device may adopt a structure configured to provide the reflecting mirror outside the transparent substrate and to emit the light from the emission interface to the outside through the second transparent electrode layer. In this case, it is possible to provide the reflecting mirror by forming a metal film on an outer surface of the transparent substrate. Alternatively, it is possible to use the reflecting mirror as the substrate and to form the OLED device thereon.

As the material of the transparent substrate, glass, polyethylene terephthalate (PET), polycarbonate, amorphous polyolefin, and the like are applicable.

Meanwhile, the first transparent electrode layer and the second transparent electrode layer can be formed as transparent conductive films by use of ITO, IZO, SnO₂, ZnO, and the like. Here, the film thickness of each of the electrode layers can be formed in a range of from 10 to 500 nm.

In addition to the structures shown in FIG. 4 and FIG. 7, the OLED device may have various other structures, including: forming the organic material layer on the transparent substrate by sequentially laminating the hole injection layer, the hole transport layer, the light emitting layer, and the electron transport layer viewed from the first transparent electrode layer; forming the organic material layer by sequentially laminating the hole injection layer, the hole transport layer, and the light emitting layer; forming the organic material layer by sequentially laminating the hole transport layer, the light emitting layer, and the electron transport layer; forming the light emitting layer as a multilayer structure; and the like.

The hole injection layer and the hole transport layer can function to promote injection of the holes from the first transparent electrode layer, to transport the holes, and to block electrons. It is sometimes beneficial to use a material having high hole mobility, transparency, and a fine film-forming characteristic for these layers. For example, triphenylamine derivatives such as triphenyldiamine (TPD), polyolefin compounds such as phthalocyanine or copper phthalocyanine, hydrazone derivatives, arylamine derivatives, and the like are applicable thereto. In the invention, the hole transport layer may be deemed to include the hole injection layer that can function to promote injection of holes from the anode, and the hole transport layer that can function to transport the holes and to block the electrons when appropriate. The film thickness of each of the hole injection layer and the hole transport layer can be set in a range of from 10 to 200 nm.

The light emitting layer is expected to have high emission efficiency attributable to recombination of holes and electrons and a fine film-forming characteristic. Meanwhile, the light emitting layer is expected not to cause a strong interaction on an interfacial plane with the material of the transport layer. For example, aluminum chelate complexes (Alq₃), distyryl arylene (DSA) derivatives such as distyryl biphenyl derivatives (DPVBi), quinacridone derivatives, rubrenes, courmarins, perylenes, and like are applicable thereto. These materials may be used either independently or in combination of two or more. It is also possible to form the light emitting layer as a multilayer structure. The film thickness of the light emitting layer can be set in a range of from 10 to 200 nm.

Aluminum chelate complexes (Alq₃), distyryl biphenyl derivatives (DPVBi), oxadiazole derivatives, distyrylanthracene derivatives, benzoxazolyl thiophene derivatives, and the like can be used as the material for forming the electron transport layer. Here, the film thickness of the electron transport layer can be set in a range of from 10 to 200 nm.

Meanwhile, it is also possible to form an electron injection layer either on the organic light emitting layer or on the electron transport layer to promote injection of electrons from the second transparent electrode layer. Metal having a low work function such as Li, Ca, Sr, or Cs is mainly used as the material of the electron injection layer. It may be preferable to deposit a very small amount of the electron injection layer on the organic material layer.

A further concrete embodiment of the OLED device according to the invention includes

a thin film multilayer structure having a transparent substrate, a first transparent electrode, a plurality of thin film layer including a light emitting layer, and a second transparent electrode in this order, and can further include a first buffer layer disposed outside the second transparent electrode and which has a transparent material, and a reflecting mirror formed by depositing a metal on the first buffer layer. In this LED device, an optical path length from the emission interface of the light emitting layer to the reflecting mirror and an optical path length from the emission interface to the outer surface of the transparent substrate are equal to, or more than, a coherent length of light emitted from the emission interface. Here, a difference in refractive index between the transparent material for the first buffer layer and the second transparent electrode adjacent thereto and a difference in refractive index between the transparent substrate and the first transparent electrode adjacent thereto are equal to, or less than, 0.6. Here, the first buffer layer may include a plurality of layers each made of a different material.

Yet another concrete embodiment of the LED device according to the invention includes a thin film multilayer structure having a transparent substrate, a first transparent electrode, a plurality of thin film layer including a light emitting layer having an emission interface, and a second transparent electrode in this order. The multilayer structure can include a reflecting mirror disposed in a position outside the second transparent electrode with provision of a certain distance from the transparent electrode such that the reflection mirror is opposed to the transparent electrode, and a first buffer layer interposed between the opposed second transparent electrode and the reflecting mirror. In this LED device, an optical path length from the emission interface to the reflecting mirror and an optical path length from the emission interface to the outside surface of the transparent substrate are equal to, or more than, a coherent length of light emitted from the emission interface. Further, a difference in refractive index between the transparent substrate and the first transparent electrode adjacent thereto is equal to, or less than, 0.6. In this case, the first buffer layer may be formed of a transparent material having such a refractive index that the difference from the second transparent electrode is equal to, or less than, 0.6. The first buffer layer may be formed as a vacuum or formed from material selected from the group consisting of a gas and a liquid. The reflecting mirror may be formed by depositing a reflecting material on a surface of the substrate, or formed of a metal plate.

Another concrete embodiment of the LED device according to the invention includes a thin film multilayer structure having a transparent substrate, a first transparent electrode, a plurality of thin film layer including a light emitting layer having an emission interface, and a second transparent electrode in this order. The multilayer structure further has a reflecting mirror formed by depositing a metal film on the outer surface of the transparent substrate, and a first buffer layer formed of a transparent material on the second transparent electrode. In this LED device, an optical path length from the emission interface to the reflecting mirror and an optical path length from the emission interface to the outside surface of the first buffer layer are substantially equal to, or more than, a coherent length of light emitted from the emission interface. Further, a difference in refractive index between the transparent material for the first buffer layer and the second transparent electrode adjacent thereto and a difference in refractive index between the transparent substrate and the first transparent electrode adjacent thereto are substantially equal to, or less than, 0.6.

### EXAMPLES

Next, Examples 1 to 13 concerning the OLED device of the invention and Comparative Examples 1 to 5 will be described. First, in Examples 1 to 12 the structure of the OLED device according to the embodiment of the invention shown in FIG. 4 was used as a basic structure. Accordingly, the common constituents in the structures of Examples 1 to 9 will be described below.

### Examples 1 to 9

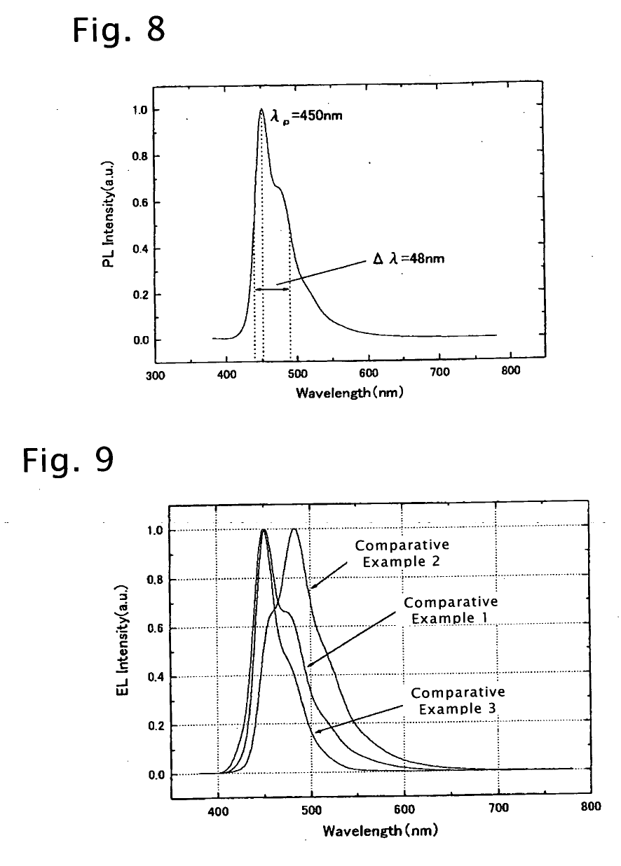

An ITO transparent electrode constituting the first transparent electrode layer (the anode) 1 was formed on a glass substrate constituting the transparent substrate 2 by the sputtering method. Sheet resistance of ITO was set to 10 ohm/sq. Then, the ITO transparent electrode 1 was etched into a given shape, and was subjected to ultrasonic cleaning by use of acetone, isopropyl alcohol, and/or the like. Thereafter, the ITO transparent electrode 1 was dried. Moreover, the glass substrate 2 was further subjected to UV-O₃ cleaning, and was set in a vacuum deposition chamber. The pressure inside the chamber was reduced to about 1×10⁻⁵ Torr, and the hole transport layer 4 was formed on the ITO transparent electrode 1 in the film thickness of 100 nm. Subsequently, the organic light emitting layer 5 with addition of a blue light-emitting material configured to emit light having an emission spectrum shown in FIG. 8 (such a material will be hereinafter referred to as a “blue light-emitting dopant”) at a concentration of 1% by weight was codeposited thereon. Then, a very small amount of the electron injection layer was deposited thereon. Thereafter, an IZO transparent electrode was formed thereon as the second transparent electrode layer (the cathode) 6 in the film thickness of 50 nm by the sputtering method. Further, a SiO film was formed thereon as the first buffer layer, and then an Al film was deposited thereon as the reflecting mirror 8. Here, the refractive index of the SiO layer was set to 1.90 relative to light having a wavelength of 450 nm.

In Examples 1 to 9, the film thickness of the SiO layer formed as the first buffer layer was changed. In this way, the optical path lengths from the emission interface 7 to the Al reflecting mirror 8 was changed. The film thicknesses and the optical path lengths in these Examples are shown in Table 1.

TABLE 1

| | | Optical path length from |
|---|---|---|
| | Film Thickness of First | Emission Interface to Al |
| Example No. | Buffer (SiO) Layer (nm) | Reflecting Mirror (nm) |
| 1 | 525 | 1285 |
| 2 | 784 | 1776 |
| 3 | 998 | 2183 |
| 4 | 1699 | 3515 |
| 5 | 2595 | 5217 |
| 6 | 3841 | 7585 |
| 7 | 4815 | 9435 |
| 8 | 6373 | 12395 |
| 9 | 7638 | 14800 |

### Example 10

In Example 10, the configuration ranging from the glass substrate 2 to the IZO transparent electrode 6 was similar to Examples 1 to 9 described above, whereas an oil layer in the film thickness of about 0.5 mm was formed on the IZO transparent electrode 6 instead of the first buffered layer and the reflecting mirror 8. The refractive index of the oil layer was set to 1.55 relative to the light having the wavelength of 450 nm.

### Example 11

In Example 11, N₂ gas was filled in a clearance of 18 μm defined between the IZO transparent electrode 6 and the reflecting mirror 8 instead of the oil layer used in Example 10. The reflecting mirror 8 was prepared by depositing Ag on a substrate. This reflecting mirror 8 was disposed such that a reflection surface thereof was opposed to the IZO transparent electrode 6. Moreover, an UV curable sealing agent, in which gap agents having a size of 18 μm were dispersed, was coated on the outer periphery of the clearance defined by the reflecting mirror 8 and the IZO transparent electrode 6, and they were attached and fixed to each other. Then N₂ gas was filled in the space surrounded by the reflecting mirror 8, the IZO transparent electrode 6, and the sealing agent.

### Example 12

In Example 12, oil having the refractive index of 1.55 relative to the light having the wavelength of 450 nm was filled instead of N₂ gas used in Example 11.

### Example 13

In Example 13 the structure of the OLED device according to the different embodiment of the invention shown in FIG. 7 was used as a basic structure (however, only two light emitting units 31 and 32 were provided therein). To be more precise, an ITO transparent electrode constituting the first transparent electrode layer (the anode) 1 was formed on a glass substrate constituting the transparent substrate 2 by the sputtering method. Sheet resistance of ITO was set to 10 ohm/sq. Then, the ITO transparent electrode 1 was etched into a given shape, and was subjected to ultrasonic cleaning by use of acetone, isopropyl alcohol, and the like. Thereafter, the ITO transparent electrode 1 was dried. Moreover, the glass substrate 2 was further subjected to UV-O₃ cleaning, and was set in a vacuum deposition chamber. The pressure inside the chamber was reduced to about 1×10⁻⁵ Torr, and the hole transport layer was formed on the ITO transparent electrode 1. Subsequently, the organic light emitting layer with addition of the blue light-emitting dopant configured to emit the light having the emission spectrum shown in FIG. 8 at the concentration of 1% by weight was codeposited thereon. This lamination structure of the hole transport layer and the organic light emitting layer was defined as a light emission unit 31. After forming the charge generating layer 41 on this light emission unit 31, another light emission unit 32 including the organic light emitting layer with addition of a yellow light-emitting dopant was formed. Further, a very small amount of the electron injection layer was deposited thereon, and an IZO transparent electrode 6 was formed thereon. Then, the reflecting mirror 8 formed by depositing Ag on the substrate was disposed such that the reflection surface thereof was opposed to the IZO transparent electrode 6. Moreover, the UV curable sealing agent, in which the gap agents having the size of 18 μm were dispersed, was coated on the outer periphery of the clearance defined by the reflecting mirror 8 and the IZO transparent electrode 6, and they were attached and fixed to each other. Then, oil having the refractive index of 1.6 relative to the light having the wavelength of 450 nm was filled in the space surrounded by the reflecting mirror 8, the IZO transparent electrode 6, and the sealing agent.

### Comparative Examples 1 to 3

In Comparative Examples 1 to 3 the structure of the conventional OLED device shown in FIG. 2 was used as a basic structure. As for the structure of Comparative Example 1, an ITO transparent electrode constituting the first transparent electrode layer (the anode) 1 was formed on a glass substrate constituting the transparent substrate 2 by the sputtering method. Sheet resistance of ITO was set to 10 ohm/sq. Then, the ITO transparent electrode 1 was etched into a given shape, and was subjected to ultrasonic cleaning by use of acetone, isopropyl alcohol, and the like. Thereafter, the ITO transparent electrode 1 was dried. Moreover, the glass substrate 2 was further subjected to UV-O₃ cleaning, and was set in a vacuum deposition chamber. The pressure inside the chamber was reduced to about 1×10⁻⁵ Torr, and the hole transport layer 4 was formed on the ITO transparent electrode 1 in the film thickness of 100 nm. Subsequently, the organic light emitting layer 5 with addition of the blue light-emitting dopant configured to emit the light having the emission spectrum shown in FIG. 8 at the concentration of 1% by weight was codeposited in the film thickness of 62 nm. Then, a very small amount of the electron injection layer was deposited thereon. Thereafter, Al was deposited thereon in the film thickness of 200 nm as the cathode 6. Here, the refractive index of the organic light emitting layer 5 was set to 1.80 relative to the light having the wavelength of 450 nm. In this case, the optical path length from the emission interface 7 to the Al cathode 6 was equal to 112 nm, which was almost equivalent to ¼ of the peak emission wavelength of 450 μm.

The structure of Comparative Example 2 is substantially similar to the structure of Comparative Example 1 described above. However, the structure of Comparative Example 2 is different from the structure of Comparative Example 1 in that the film thickness of the organic light emitting layer 5 formed by codeposition with the blue light-emitting dopant was set to 105 nm, and that the optical path length from the emission interface 7 to the Al cathode 6 was set to 189 nm, which was deviated from a value calculated by multiplying ¼ of the peak emission wavelength of 450 nm by an odd number.

The structure of Comparative Example 3 is similar to the structure of Comparative Example 2 described above from the glass substrate 2 to the organic light emitting layer 5 by means of codeposition with the blue light-emitting dopant. However, the structure of Comparative Example 3 is different from the structure of Comparative Example 2 in that a very small amount of the electron injection layer was formed on the organic light emitting layer 5, that an IZO transparent electrode 6 was formed thereon in the film thickness of 50 nm by the sputtering method, and that Al was further formed thereon in the film thickness of 200 nm as the reflecting mirror. Here, the refractive index of the IZO transparent electrode 6 was set to 1.95 relative to the light having the wavelength of 450 nm. As a result, the optical path length from the emission interface 7 to the Al reflecting mirror set to 286 nm, which was deviated from a value calculated by multiplying ¼ of the peak emission wavelength of 450 nm by an odd number as similar to Comparative Example 2.

### Comparative Example 4

In Comparative Example 4, the Al reflecting mirror was removed from the structure of Comparative Example 3, and the space above the IZO transparent electrode 6 was filled with N₂ gas.

### Comparative Example 5

In Comparative Example 5, the structure shown in FIG. 7 was used as a basic structure, and two light emitting units 31 and 32 were provided therein. To be more precise, an ITO transparent electrode constituting the first transparent electrode layer (the anode) 1 was formed on a glass substrate constituting the transparent substrate 2 by the sputtering method. Sheet resistance of ITO was set to 10 ohm/sq. Then, the ITO transparent electrode 1 was etched into a given shape, and was subjected to ultrasonic cleaning by use of acetone, isopropyl alcohol, and the like. Thereafter, the ITO transparent electrode 1 was dried. The glass substrate 2 was further subjected to UV-O₃ cleaning, and was set in a vacuum deposition chamber. The pressure inside the chamber was reduced to about 1×10⁻⁵ Torr, and the hole transport layer was formed on the ITO transparent electrode 1. Subsequently, the organic light emitting layer with addition of the blue light-emitting dopant configured to emit the light having the emission spectrum shown in FIG. 8 at the concentration of 1% by weight was codeposited thereon. This lamination structure of the hole transport layer and the organic light emitting layer was defined as a light emission unit 31. After forming the charge generating layer 41 on this light emission unit 31, another light emission unit 32 including the organic light emitting layer with addition of the yellow light-emitting dopant was formed. Further, a very small amount of the electron injection layer was deposited thereon, and an Al cathode was finally deposited in the film thickness of 200 nm.

### Optical Characteristics of Examples 1-13 and Comparative Examples 1-5

FIG. 9 shows emission spectra of the OLED devices of Comparative Examples 1 to 3, which have conventional structures.

The OLED device of Comparative Example 1 is the device configured to set the optical path length from the emission interface to the Al electrode approximately equal to λₚ/4 (the peak wavelength of the emitted light λₚ=450 nm). Distribution of the emission spectrum thereof is substantially similar to distribution of a PL spectrum of the blue light-emitting dopant shown in FIG. 8.

Meanwhile, when the film thickness of the organic light emitting layer is set equal to 105 nm as shown in Comparative Example 2, distribution of the emission spectrum thereof is very different from the distribution of the PL spectrum of the blue light-emitting dopant. This is attributable to the fact that the optical path length from the emission interface to the Al electrode is deviated from the value calculated by multiplying λₚ/4 (the peal wavelength of the emitted light λₚ=450 nm) by an odd number.

Moreover, the optical path length from the emission interface to the Al electrode is deviated from the value calculated by multiplying λₚ/4 (the peak wavelength of the emitted light λₚ=450 nm) by an odd number similarly in Comparative Example 3. Accordingly, distribution of the emission spectrum thereof is different from the distribution of the PL spectrum of the blue light-emitting dopant.

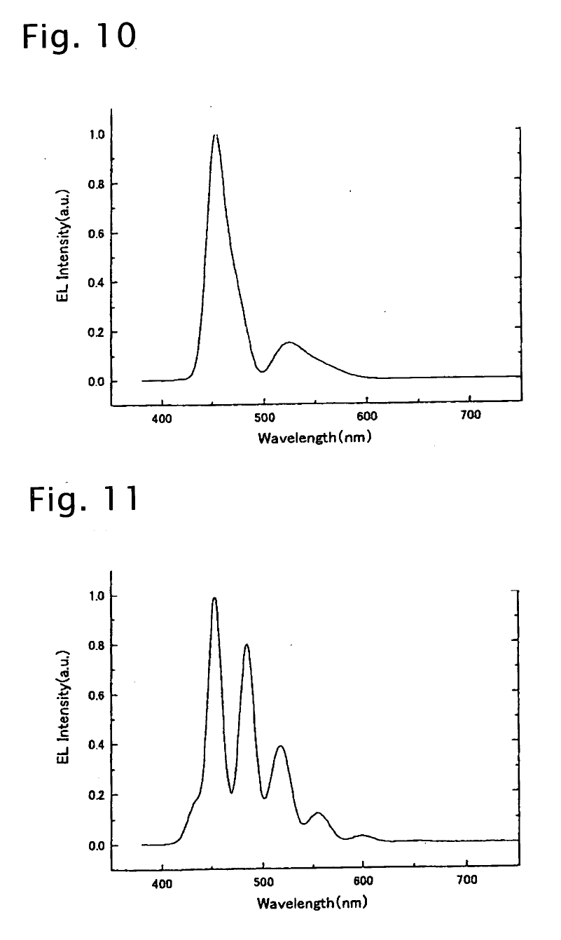

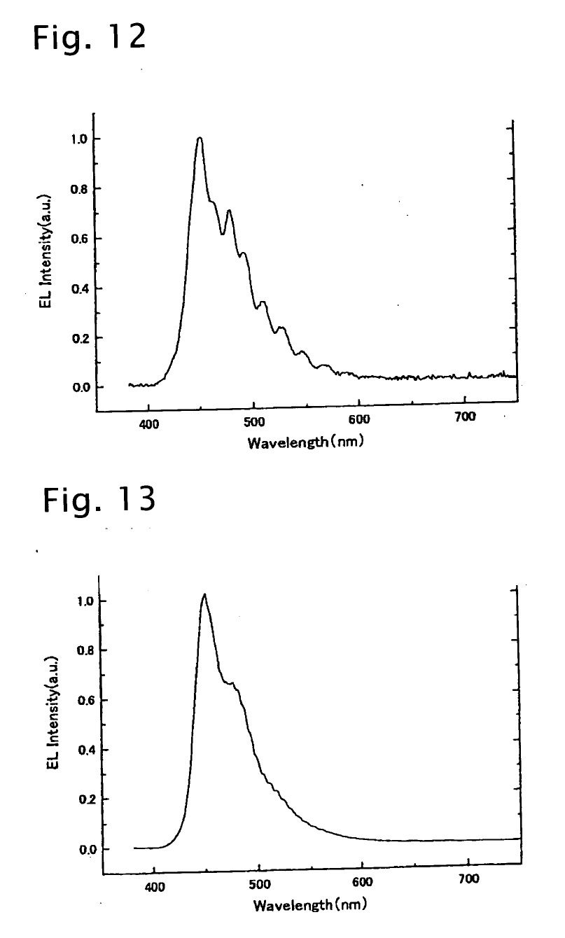

FIG. 10 shows an emission spectrum of Example 1. FIG. 11 shows an emission spectrum of Example 4. FIG. 12 shows an emission spectrum of Example 6. FIG. 13 shows an emission spectrum of Example 9.

Distribution of the emission spectrum of the OLED device of Example 1 shown in FIG. 10 is very different from that of the PL spectrum of the blue light-emitting dopant due to an influence of interference. However, when the optical path length from the emission interface to the Al reflecting mirror is gradually extended by increasing the film thickness of the first buffer (SiO) layer as shown in Examples 2 to 9, the distribution of the emission spectrum as shown in FIGS. 11 to 13 gradually comes close to the distribution of the PL spectrum of the blue light-emitting dopant.

Now, in accordance with another aspect of the invention, a concept of a “degree of modulation” will be described as a method of objectively indicating a degree of approximation concerning the distribution of the emission spectrum.

First, relative luminosity of the distribution of the emission spectrum of the light being an object of comparison is divided by relative luminosity of distribution of an emission spectrum of reference light in terms of each wavelength. In this way, distribution of a modulation spectrum is calculated. Then, in terms of the distribution of the modulation spectrum, the “degree of modulation (V)” is derived from the maximum value (I_{MAX}) and the minimum value (I_{MIN}) existing in a range of the emission wavelength subject to assessment of the degree of approximation by using the following formula:
V=(I_{MAX}−I_{MIN})/(I_{MAX}+I_{MIN}).

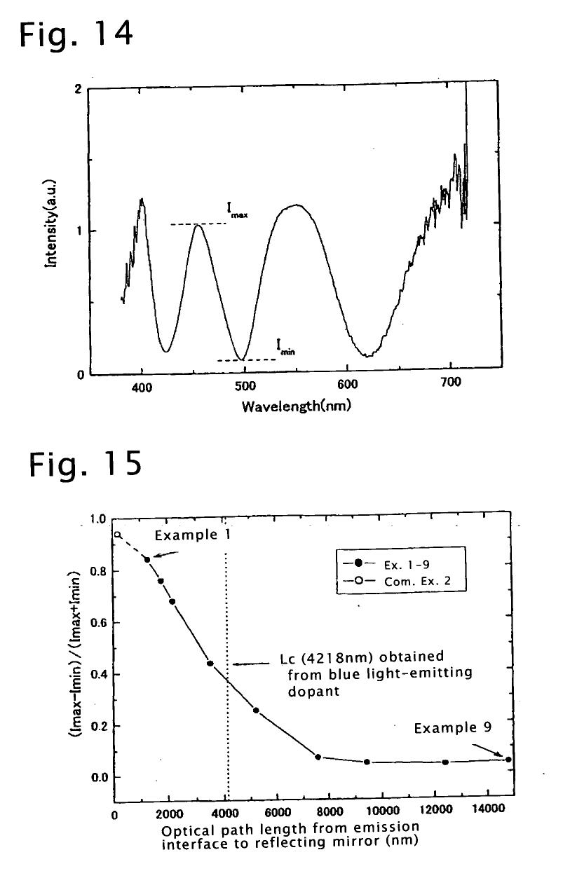

FIG. 14 shows an example of the distribution of the modulation spectrum on the assumptions that the light emitted from the OLED device of Example 1 is defined as the light to be compared, and that the light emitted from the blue light-emitting dopant is defined as the reference light. The degree of modulation is calculated by use of this distribution of the modulation spectrum and the above-mentioned formula.

FIG. 15 illustrates relationships between the “optical path lengths from the emission interface to the reflecting mirror” and the “degrees of modulation” in terms of the OLED devices of Examples 1 to 9 and Comparative Example 2, in which the light emitted from each of the OLED devices of Example 1 to 9 and Comparative Example 2 is defined as the light to be compared and the light emitted from the blue light-emitting dopant is defined as the reference light.

The degrees of modulation in the OLED devices having the optical path lengths from the emission interface to the cathode (or to the reflecting mirror) in a range of several tens to several hundreds of nanometers were nearly equal to 1. For example, the degree of modulation in the OLED device of Comparative Example 2 was equal to 0.94. On the contrary, the degree of modulation at a value (4218 nm) equivalent to the coherent length Lc of the light emitted from the blue light-emitting dopant plotted with a dashed line in the drawing was approximately equal to 0.36. Although there was a little interference, it was confirmed that its influence was substantially reduced. Therefore, it was confirmed that the “degree of modulation” obtained by the above-described method should be set approximately equal to or below 0.36 in order to establish a standard for minimizing the influence of interference in the OLED device.

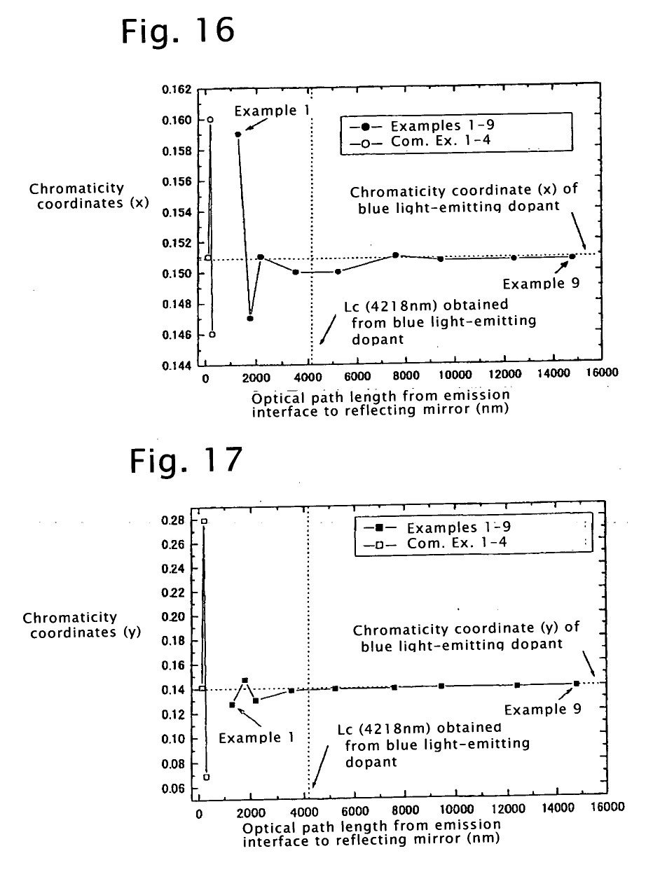

Meanwhile, one of the characteristics of the OLED device is that the OLED device is self-luminous. Accordingly, its luminescent color is also an important factor. Given this factor, relationships between the “optical path lengths from the emission interface to the reflecting mirror” and “chromaticity” of the luminous color were investigated in terms of the OLED devices of Examples 1 to 9 and Comparative Examples 1 to 4. Results are shown in FIG. 16 and FIG. 17. FIG. 16 shows the chromaticity coordinates (x), while FIG. 17 shows the chromaticity coordinates (y).

In the OLED device having the optical path lengths from the emission interface to the cathode (the reflecting mirror) in the range of several tens to several hundreds of nanometers as shown in Comparative Examples 1 to 3, it was apparent that the chromaticity (x, y) drastically changed by a subtle change in the film thickness. On the contrary, the optical path length from the emission interface to the cathode (or the reflecting mirror) was gradually extended as shown in Examples 1 to 9. When the optical path length was set equal to or above the value (4218 nm) equivalent to the coherent length Lc of the light emitted from the blue light-emitting dopant as plotted with the dashed line in the drawing, it was apparent that a difference in the chromaticity relative to the light originally emitted from the blue light-emitting dopant (at the time of PL emission) is reduced to 0.01 or below in terms of the x value as well as the y value.

In other words, an effect to suppress the interference became larger as the optical path length from the emission interface to the cathode (or the reflecting mirror) was larger. Even when the length was small, it was confirmed that these embodiments were able to exert higher effects to suppress the influence of interference than the configurations of Comparative Examples. In particular, by setting the optical path length equal to or above the value (4218 nm) equivalent to the coherent length Lc of the light emitted from the blue light-emitting dopant, it was possible to reproduce the chromaticity of the light originally emitted from the blue light-emitting dopant to a large extent. Moreover, it is apparent that the chromaticity changed very little along with the slight change in the film thickness.

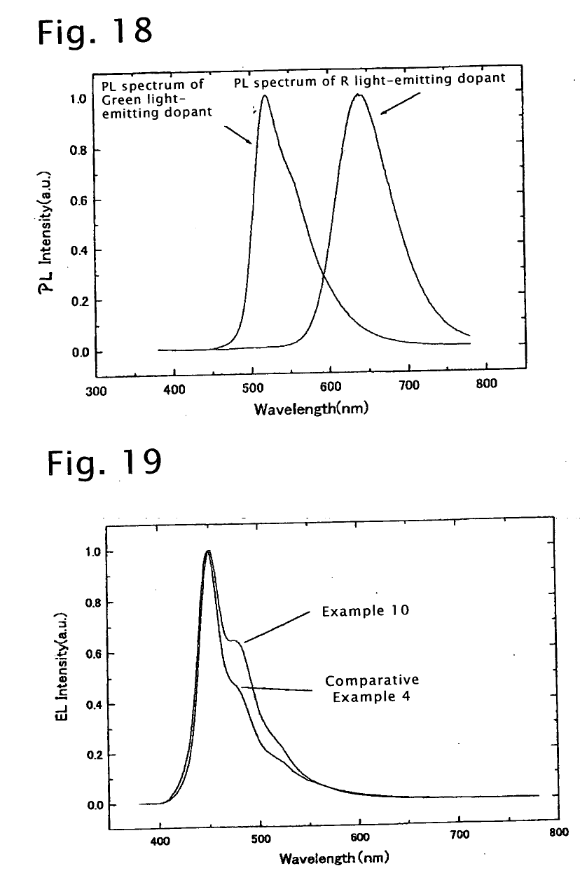

Next, characteristics were confirmed in terms of OLED devices including the organic light emitting layers with addition of a green light-emitting dopant and a red light-emitting dopant configured to emit light having PL spectra as shown in FIG. 18. Here, the green light-emitting dopant and the red light-emitting dopant were used in the structures similar to the OLED devices of Examples 1 to 9 as the dopant to be added to the organic light emitting layer. The degrees of modulation at values (4992 nm and 5362 nm) equivalent to the coherent lengths Lc of the light emitted from the respective dopants are shown in Table 2 below. Concerning the OLED devices configured to emit the luminous colors other than blue, results confirmed therein were similar to the case of the blue-emitting OLED devices.

TABLE 2

| Luminous Color of | Coherent Length Lc Obtained | Degree of |
|---|---|---|
| Dopant | by PL Spectrum (nm) | Modulation |
| Blue | 4218 | 0.360 |
| Green | 4992 | 0.340 |
| Red | 5362 | 0.355 |

FIG. 19 shows the emission spectra of the light emitted from the glass substrate side of the OLED devices of Comparative Example 4 and Example 10. In Comparative Example 4, the structure in which the space above the IZO transparent electrode having the refractive index of 1.95 relative to the light having the wavelength of 450 nm was filled with N₂ gas was used. In Example 10, the structure in which the oil layer having the refractive index of 1.55 relative to the light having the wavelength of 450 ; nm was formed in the film thickness of about 0.5 mm above the IZO transparent electrode was used.

The difference in the refractive index between the IZO transparent electrode and N₂ gas was equal to 0.95 in Comparative Example 4. Meanwhile, the difference in the refractive index between the IZO transparent electrode and the oil layer was equal to 0.4 in Example 10.

As a result, the distribution of the emission spectrum of Comparative Example 4 was different from the spectral distribution of the light emitted from the blue light-emitting dopant shown in FIG. 8, and reflected the influence of interference. On the contrary, the distribution of the emission spectrum of Example 10 was substantially the same as the spectral distribution of the light emitted from the blue light-emitting dopant.

Accordingly, it was confirmed that interference might be caused even when the difference in the refractive index between the two layers constituting the interfacial plane was around 0.95. At the same time, it was also confirmed that the problem of interference was solved by reducing this difference in the refractive index.

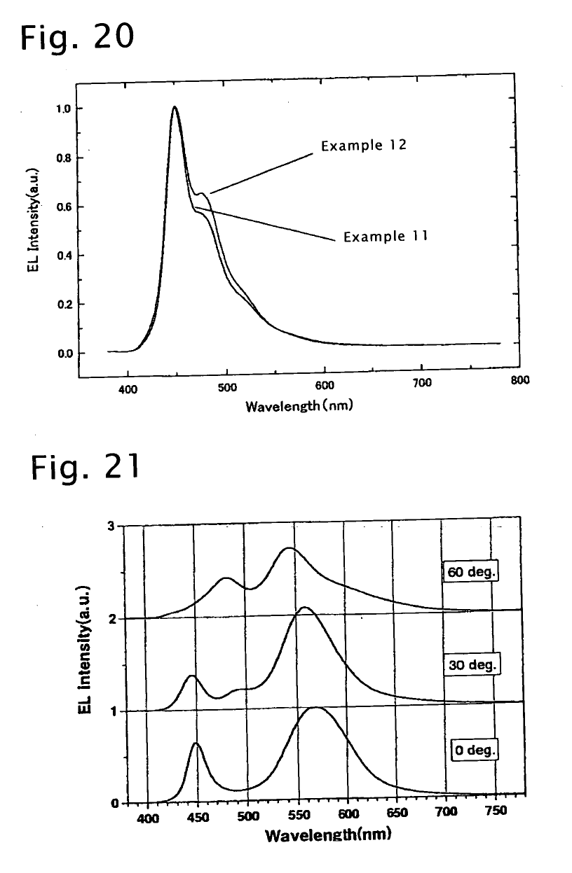

FIG. 20 shows the emission spectra of the light emitted from the glass substrate side of the OLED devices of Examples 11 and 12. In Example 11, the clearance surrounded by the reflecting mirror, the IZO transparent electrode, and the sealing agent was filled with N₂ gas. Meanwhile, in the OLED device of Example 12, the clearance was filled with the oil having the refractive index of 1.55 relative to the light having the wavelength of 450 nm.

The distribution of the emission spectrum of Comparative Example 4 in which the structure of filling the space above the IZO transparent electrode simply with N₂ gas (FIG. 19) was used was compared with the distribution of the emission spectrum of Example 11 in which the structure of further providing the reflecting mirror thereon by depositing Ag was used. Here, it is apparent that the distribution of the emission spectrum of Example 11 is closer to the distribution of the PL spectrum of the blue light-emitting dopant. In other words, it was confirmed that the reflecting mirror disposed opposite to the IZO transparent electrode could suppress the influence of interference.

Moreover, the distribution of the emission spectrum of Example 12 in which the structure to fill the space with the oil was used was substantially similar to the distribution of the PL spectrum of the blue light-emitting dopant.

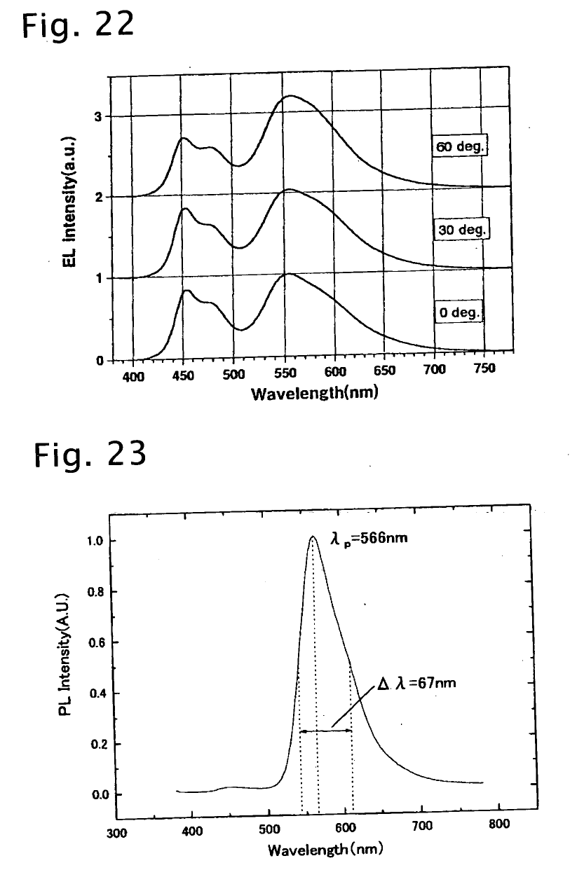

FIG. 21 and FIG. 22 show the emission spectra of the OLED devices of Comparative Example 5 and Example 13, in which the structure of including two light emitting portions was used (namely, the light emission unit having the organic light emitting layer formed by codepositing the blue light-emitting dopant, and the light emission unit having the organic light emitting layer formed by codepositing the yellow light-emitting dopant). In Comparative Example 5, the structure in which Al constituting the cathode was formed directly on the electron injection layer in the film thickness of 200 nm was used. Meanwhile, in Example 13 the structure was used in which the reflecting mirror was disposed such that the reflection surface was opposed to the IZO transparent electrode, and the oil having the refractive index of 1.6 relative to the light having the wavelength of 450 nm was filled in the space surrounded by the reflecting mirror, the IZO transparent electrode, and the sealing agent.

When the emission surface of the OLED device is viewed from a direction of a normal line (0 deg) to the emission surface, neither the distribution of the PL spectrum of the blue light-emitting dopant nor the distribution of the PL spectrum of the yellow light-emitting dopant is reproduced by the emission spectrum of the OLED device of Comparative Example 5 shown in FIG. 21. In addition, the spectral distribution significantly changes depending on the viewing angle (crossing angles of 30 deg and 60 deg relative to the normal line to the emission surface).

On the contrary, when viewed from the direction of the normal line, the emission spectrum of the OLED device of Example 13 shown in FIG. 22 reproduces both of the distribution of the PL spectrum of the blue light-emitting dopant and the distribution of the PL spectrum of the yellow light-emitting dopant to a large extent. Moreover, the change in the spectral distribution is hardly observed along with the change in the viewing angle.

As described above, the OLED device can be configured to allow the organic material layer, which is interposed between the two opposed transparent electrode, to include the plurality of light emission units each having at least one light emitting layer. Moreover, the respective light emission units are partitioned by at least one layer of the charge generating layer. It was confirmed that the OLED device of the above-described structure could achieve the effects similar to an OLED device having one light emitting layer.

Next, Examples 14 to 20 concerning certain embodiments of the OLED device of the invention and Comparative Example 6 will be described.

### Example 14

In Example 14, the structure of Comparative Example 4 was used except for the configuration that oil having the refractive index of 1.55 was filled in a clearance of 18 μm defined by the IZO transparent electrode and a sealing glass substrate disposed opposite to the IZO transparent electrode instead of N₂ gas used in Comparative Example 4. The clearance of 18 μm between the IZO transparent electrode and the sealing glass substrate was secured by attaching and fixing the glass substrate formed with the device on the upper surface to the sealing glass substrate disposed to seal the device, by use of the UV curable sealing agent including the gap agents dispersed therein.

### Examples 15 to 17

In Examples 15 to 17, the structure of Example 14 was used except for the configuration that three types of oil having the refractive indices of 1.33, 1.37, and 1.43 were filled in the clearances between the IZO transparent electrode and the sealing glass substrate, respectively. Other conditions were similar to those in Example 14.

### Example 18

In Example 18, the structure of Comparative Example 5 was used except for the configuration that oil having the refractive index of 1.55 was filled in a clearance of 18 μm defined by the IZO transparent electrode and a sealing glass substrate disposed opposite to the IZO transparent electrode instead of N₂ gas used in Comparative Example 5. The clearance was secured by a similar method to Example 14.

### Examples 19 and 20

In Examples 19 and 20, the structure of Example 18 was used except for the configuration that two types of oil having the refractive indices of 1.33 and 1.43 were filled in the clearances between the IZO transparent electrode and the sealing glass substrate, respectively. Other conditions were similar to those in Example 18.

### Comparative Example 6

An ITO transparent electrode was formed on a glass substrate having the refractive index of 1.53 relative to light having a wavelength of 560 nm by the sputtering method. The film thickness of ITO was set to 125 nm. Sheet resistance of ITO was set to 10 ohm/sq. The refractive index of ITO was set to 1.90 relative to the light having the wavelength of 560 nm. Then, the ITO transparent electrode was etched into a given shape, and was subjected to ultrasonic cleaning by use of acetone, isopropyl alcohol, and the like. Thereafter, the ITO transparent electrode was dried. The glass substrate was further subjected to UV-O₃ cleaning, and was set in a vacuum deposition chamber. The pressure inside the chamber was reduced to about 1×10⁻⁵ Torr, and the hole transport layer was formed on the ITO transparent electrode in the film thickness of 100 nm. Subsequently, the organic light emitting layer with addition of a yellow light-emitting dopant configured to emit light having an emission spectrum shown in FIG. 23 at a concentration of 1% by weight was codeposited thereon. Then, a very small amount of the electron injection layer was deposited thereon. Thereafter, an IZO transparent electrode was formed thereon as the cathode in the film thickness of 50 nm by the sputtering method. Here, the refractive index of the organic light emitting layer was set to 1.75 relative to the light having the wavelength of 560 nm. Meanwhile, the refractive index of the IZO transparent electrode was set to 1.90 relative to the light having the wavelength of 560 nm. The space above the IZO surface was filled with N₂ gas.

### Characteristics of Examples 14-20 and Comparative Examples 4 and 6

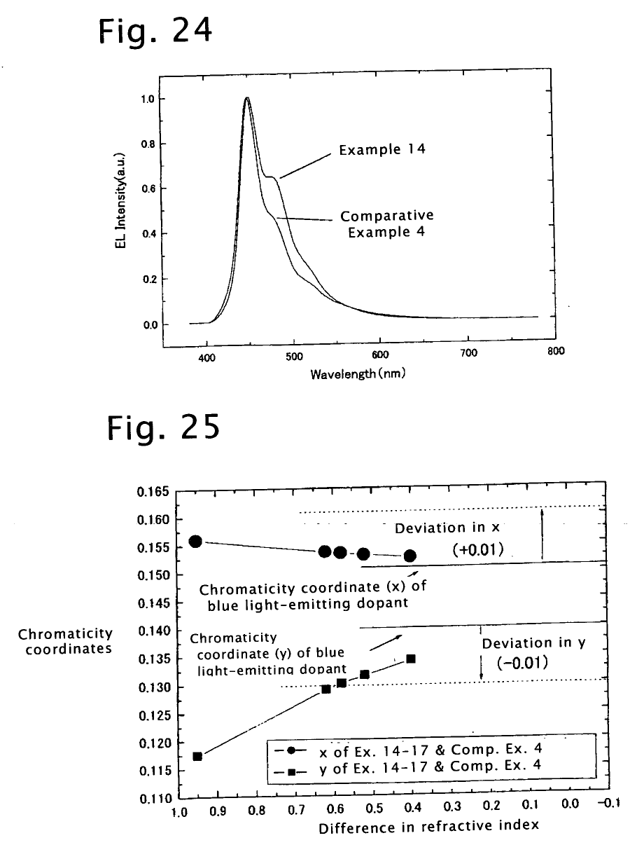

FIG. 24 shows the emission spectra of the light emitted from the glass substrate side of the OLED devices of Comparative Example 4 and Example 14. In Comparative Example 4, the structure was used in which the space above the IZO transparent electrode having the refractive index of 1.95 relative to the light having the wavelength of 450 nm was filled with N₂ gas. Meanwhile, in Example 14 the structure was used in which the oil layer having the refractive index of 1.55 relative to the light having the wavelength of 450 nm was provided on the IZO transparent electrode.

Accordingly, the difference in the refractive index between the IZO transparent electrode and N₂ gas in Comparative Example 4 was equal to 0.95, and the difference in the refractive index between the IZO transparent electrode and the oil layer in Example 14 was equal to 0.4. As a result of comparison of the distribution of the emission spectra between Comparative Example 4 and Example 14, the distribution of the emission spectrum of Comparative Example 4 is different from the spectral distribution of the light emitted from the blue light-emitting dopant shown in FIG. 8.

This is presumably due to the fact that the reflection surface having the difference in the refractive index of 0.95, which is caused between IZO and N₂ gas, exists in the position at the optical path length from the emission interface shorter than the coherent length Lc (about 4.2 μm) that is derived from the PL spectrum of the blue light-emitting dopant of FIG. 8, and that the distribution of the emission spectrum of Comparative Example 4 is significantly affected by the interference.

On the contrary, the distribution of emission spectrum of Example 14 is substantially the same as the spectral distribution of the light emitted from the blue light-emitting dopant shown in FIG. 8. This is presumably due to the fact that the oil having the refractive index of 1.55 was filled instead of N₂ gas used in Comparative Example 4, and that the difference in the refractive index between IZO and the oil was reduced to 0.4.

From these results, it was apparent that the interference might be caused even when the difference in the refractive index existing in the position at the optical path length from the emission interface being shorter than the coherent length Lc (about 4.2 μm) had a value around 0.95. Moreover, it was apparent that the influence of interference to the emission could be suppressed by minimizing the difference in the refractive index.

FIG. 25 shows relationships between chromaticity coordinates (x, y) of the light emitted from the glass substrate side and the difference in the refractive index caused by the IZO transparent electrode and the material constituting the interfacial plane with the IZO transparent electrode in terms of Examples 14 to 17 and Comparative Example 4. From this drawing, it is apparent that the influence of interference with the light emitted from the glass substrate side becomes smaller along with a decrease in the difference in the refractive index. As a consequence, the chromaticity coordinates (x, y) of the light emitted from the glass substrate side gradually approach the chromaticity coordinates (x, y) derived from the PL spectrum unique to the blue light-emitting dopant.

Moreover, when the difference in the refractive index is equal to or below 0.6, deviation from the chromaticity coordinates (x, y) of the blue light-emitting dopant becomes equal to or below 0.01 in terms of the x value and the y value. In this way, it was apparent that the deviation of the chromaticity could be suppressed to an indiscernible level in terms of the color discrimination power of a human being.

From these results, it was apparent that the difference in the refractive index might cause the interference even at the value around 0.95, provided that the difference in the refractive index exists in the position where the optical path length from the emission interface of the organic light emitting layer is shorter than the coherent length Lc. Moreover, it was apparent that the influence of interference could be suppressed by minimizing the difference in the refractive index.

Furthermore, these results indicate that there may be a case where it is not possible to reproduce the original chromaticity of the blue light-emitting dopant even if the optical path length from the emission interface to the reflecting mirror is set to a value equal to or greater than the “coherent length Lc” (4.2 μm) upon emission of the OLED device provided with the reflecting mirror. In other words, when there is an interface having a large difference in the refractive index in a position between the emission interface and the reflecting mirror at the optical path length from the emission interface below the coherent length (4.2 μm), this interface will function as the reflection surface and will affect the emission from the glass substrate surface. Therefore, in order to reproduce the original chromaticity of the blue light-emitting dopant upon emission of the device provided with the reflecting mirror, the optical path length from the emission interface to the reflecting mirror can be set equal to, or more than, the “coherent length Lc” (4.2 μm), and the difference in the refractive index existing in the position at the optical path length from the emission surface below the coherent length (4.2 μm) can be minimized (the difference in the refractive index can be adjusted to be at least equal to or below 0.6). In this way, it is possible to set the deviation from the original chromaticity coordinates of the blue light-emitting dopant within 0.01 in terms of the x value and the y value.

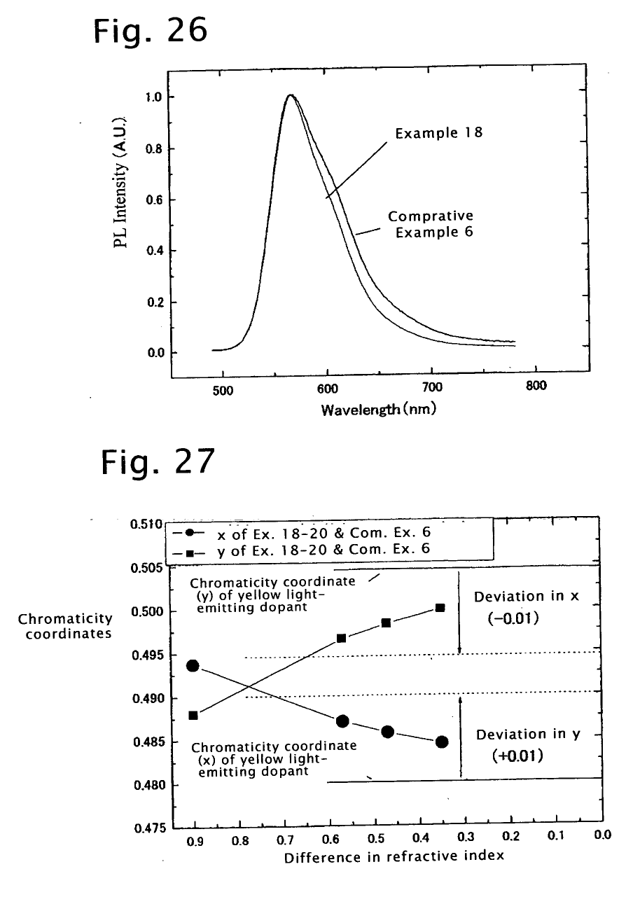

FIG. 26 shows the emission spectra of the light emitted from the glass substrate side of the OLED devices of Comparative Example 6 and Example 18. In Comparative Example 6, the structure was used in which the space above the IZO transparent electrode having the refractive index of 1.90 relative to the light having the wavelength of 560 nm was filled with N₂ gas. Meanwhile, in Example 18 the structure was used in which the oil layer having the refractive index of 1.55 relative to the light having the wavelength of 560 nm was provided on the IZO transparent electrode.

Accordingly, the difference in the refractive index between the IZO transparent electrode and N₂ gas in Comparative Example 6 was equal to 0.90, and the difference in the refractive index between the IZO transparent electrode and the oil layer in Example 18 was equal to 0.35. As a result of comparison of the distribution of the emission spectra between Comparative Example 6 and Example 18, the distribution of the emission spectrum of Comparative Example 6 is different from the spectral distribution of the light emitted from the yellow light-emitting dopant shown in FIG. 23. This is presumably due to the fact that the reflection surface having the difference in the refractive index of 0.90, which is caused by IZO and N₂ gas, exists in a position at the optical path length shorter than the coherent length Lc (about 4.8 μm that is derived from the PL spectrum of the yellow light-emitting dopant of FIG. 23), and thus the distribution of the emission spectrum of Comparative Example 6 is significantly affected by the interference.

On the contrary, the distribution of emission spectrum of Example 18 is substantially the same as the spectral distribution of the light emitted from the yellow light-emitting dopant shown in FIG. 23. This is presumably due to the fact that the oil having the refractive index of 1.55 was filled instead of N₂ gas used in Comparative Example 6, and that the difference in the refractive index between IZO and the oil was reduced to 0.35.

From these results, it was apparent that the interference might be caused even when the difference in the refractive index existing in the position at the optical path length from the emission interface shorter than the coherent length Lc (about 4.8 μm) had a value around 0.90. Moreover, it was apparent that the influence of interference to the emission could be suppressed by minimizing the difference in the refractive index.

FIG. 27 shows relationships between chromaticity coordinates (x, y) of the light emitted from the glass substrate side and the difference in the refractive index caused by the IZO transparent electrode and the material constituting the interfacial plane with the IZO transparent electrode in terms of Examples 18 to 20 and Comparative Example 6. From this drawing, it is apparent that the influence of interference with the light emitted from the glass substrate side becomes smaller along with a decrease in the difference in the refractive index. As a consequence, the chromaticity coordinates (x, y) of the light emitted from the glass substrate side gradually approach the chromaticity coordinates (x, y) derived from the PL spectrum unique to the yellow light-emitting dopant.

Moreover, when the difference in the refractive index is equal to or below 0.6, deviation from the chromaticity coordinates (x, y) of the yellow light-emitting dopant becomes equal to or below 0.01 in terms of the x value and the y value. In this way, it was apparent that the deviation of the chromaticity could be suppressed to an indiscernible level in terms of the color discrimination power of a human being.

From these results, it was apparent that the difference in the refractive index might cause the interference even at the value around 0.90, provided that the difference in the refractive index exists in the position where the optical path length from the emission interface of the organic light emitting layer is shorter than the coherent length Lc. Moreover, it was apparent that the influence of interference could be suppressed by minimizing the difference in the refractive index.

Furthermore, these results indicate that there may be a case where it is not possible to reproduce the original chromaticity of the yellow light-emitting dopant even if the optical path length from the emission interface to the reflecting mirror is set to a value equal to or greater than the “coherent length Lc” (4.8 μm) upon emission of the OLED device provided with the reflecting mirror. In other words, when there is an interface having a large difference in the refractive index in a position between the emission interface and the reflecting mirror at the optical path length from the emission interface below the coherent length (4.8 μm), this interface will function as the reflection surface and will affect the emission from the glass substrate surface. Therefore, in order to reproduce the original chromaticity of the yellow light-emitting dopant upon emission of the device provided with the reflecting mirror, the optical path length from the emission interface to the reflecting mirror can be set to be equal to, or more than, the “coherent length Lc” (4.8 μm), and the difference in the refractive index existing in the position at the optical path length from the emission surface below the coherent length (4.8 μm) can be minimized (the difference in the refractive index can be adjusted to be at least equal to or below 0.6). In this way, it is possible to set the deviation from the original chromaticity coordinates of the yellow light-emitting dopant within the 0.01 in terms of the x value and the y value.

On the assumption that the optical path length from the emission interface to the position where difference in the refractive index exists remains substantially the same in the course of comparison, it is possible to reduce the deviation of the chromaticity as the emission wavelength is longer even in the case of a relatively large difference in the refractive index. Incidentally, the human eye can detect a slight difference in the chromaticity in a blue zone but can detect only a large difference in the chromaticity in a green zone. Likewise, the human eye can detect only a larger difference in the chromaticity in a yellow zone and a red zone as compared to the blue zone. Accordingly, when the difference in the refractive index exists in the position where the optical path length from the emission interface is shorter than the coherent length, it may be desirable to set the difference in the refractive index equal to or below 0.6 and thereby to suppress the deviation of the chromaticity equal to or below 0.01. In this way, it is possible to obtain luminance in a desired color tone in any color tone perspectives, which can be recognized as equivalent to the original luminescent color of the luminescent material.

(Other Embodiments)

Next, an OLED device according to another embodiment of the invention will be described. This OLED device includes a lamination structure of a transparent substrate/a first transparent substrate/a plurality of thin film layers including a light emitting layer/a reflective electrode. The LED device further includes a second buffer layer which is formed between the light emitting layer and the reflective electrode. An optical path length from an emission interface of the light emitting layer to the reflective electrode is set substantially equal to, or more than, a coherent length of light emitted from the emission interface. Moreover, in a position at an optical path length from the emission interface of the light emitting layer being shorter than the coherent length of the light emitted from the emission surface, all differences in the refractive index between two adjacent layers except the reflective electrode are set substantially equal to or below 0.6.

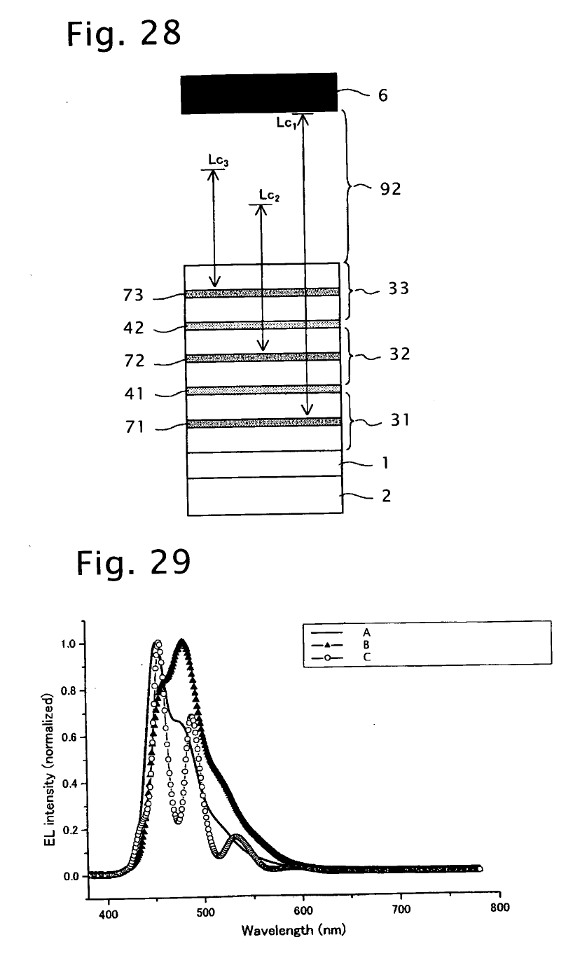

FIG. 28 is a cross-sectional view showing an exemplary structure of this embodiment. In this embodiment, an MPE structure is used, which includes a plurality of light emitting positions located separately from one another. Various combinations are conceivable in terms of light to be emitted from respective light emission units. The combinations include lamination of single-color light emission units of the same luminescent color, lamination of single-color light emission units of mutually different luminescent colors, lamination of mixed-color light emission units designed for white light, and the like.

As for the concrete structure of the OLED device shown in FIG. 28, a transparent electrode layer (an anode) 1 is formed on a transparent substrate 2. Then, a first light emission unit 31 including a first emission interface 71, a first charge generating layer 41, a second light emission unit 32 including a second emission interface 72, a second charge generating layer 42, a third light emission unit 33 including a third emission interface 73, and a second buffer layer 92 are sequentially formed thereon. Moreover, an electrode (a reflective electrode (a cathode)) 6, which is also configured to function as a reflecting mirror, is disposed in a position outside the second buffer layer 92 such that the reflection surface thereof is opposed to the third light emission unit 33.

In this way, the second buffer layer 92 is formed between the outermost light emission unit (the third light emission unit 33) of the lamination structure and the reflective electrode 6. Here, the optical path length from the emission interface of the light emitting layer to the reflective electrode 6 is set equal to, or more than, the coherent length. Further, the differences in the refractive index on all interfaces located between the emission interface and the reflective electrode 6 are set equal to, or less than, 0.6.

Therefore, upon fabrication of the device, it is possible to configure each of the light emission units in the optimal film thickness in light of carrier balance without depending on an influence of optical interference. Film thickness adjustment in the related art includes procedures of setting the optical path length from each emission interface to the cathode equal to the value calculated by multiplying λ/4 by an odd number, and utilizing conditions to intensify the optical interference effect in accordance with the thickness of the electron transport layer or the transparent electrode. However, in this embodiment, it is possible to obtain emitted light having substantially the same peak wavelength as that of the light emitted from the light emitting layer without performing such film thickness adjustment.

In particular, upon fabrication of the device having the MPE structure, a change in an optical interference condition associated with formation of the MPE structure is corrected by the second buffer layer 92 even in the case of simply laminating the light emission units 31, 32, 33 designed with the optimal film thicknesses. For this reason, it is not necessary to adjust the optical path length from each emission interface to the cathode 6 to the value calculated by multiplying λ/4 by an odd number. In other words, it is possible to laminate the light emission units having the optimal carrier balance characteristics while maintaining original desired luminescent colors of materials, and thereby to fabricate an ideal MPE device with improved efficiency.

The second buffer layer 92 has a similar function to the above-described first buffer layer, which is to adjust the optical path length from each emission interface to the cathode substantially equal to, or more than, the coherent length without affecting the carrier balance. However, the second buffer layer 92 is different from the first buffer layer in that an insulator is not applicable thereto.

Meanwhile, when the transparent electrode such as IZO is formed on the upper surface of the electron transport layer as the cathode, the transparent electrode may damage the electron transport layer and deteriorate the entire device. On the contrary, in the OLED device of this embodiment, the second buffer layer 92 on the electron transport layer also has a function to protect the electron transport layer against damage arising from sputtering film formation.

The material used for the second buffer layer 92 should meet the following requirements. Specifically, the material is not supposed to absorb light in the visible light range. The material should have high conductivity (particularly in light of an electron transport property). Moreover, the material should be non-luminescent. To be more precise, the material suitable for the second buffer layer 92 may include: a transparent electrode material as typified by IZO and ZnO; a charge generating material (also referred to as a CGL material) as typified by V₂O₅; and a thin multilayer film formed either by combination or by lamination of the aforementioned materials. Here, the “charge generating material” used herein is not a material configured to generate charges by optical excitation, which is used in an optical photoconductor (OPC) and the like. The charge generating material cited herein is expected to have the following function. Specifically, as disclosed in Japanese Patent Laid-Open Publication No. 2003-272860, the charge generating material is, for instance, used in a lamination structure in which a plurality of light emission units are arranged between an anode and a cathode opposed to each other and are partitioned by charge generating layers having a specific resistance substantially equal to or above 1.0×10² Ω·cm. In this case, when a given voltage is applied between both electrodes, the charge generating material is expected to be capable of achieving simultaneous emission of the light emission units as if the plurality of light emission units are electrically connected in series. A favorable example of the charge generating material may be a laminated film of the above-mentioned CGL material and low work function metal (such as Cs or Li) and having the structure of Li/CGL/Li/CGL/ . . . /Li/CGL, for example.

Other conceivable options for the material of the second buffer layer 92 may be an electron transport material and a hole block material. Nevertheless, generally used types of these materials may cause a significant increase in a drive voltage. Accordingly, depending on the application, it may be preferable to select a high-mobility type out of the electron transport materials and the hole block materials with a specific resistance substantially equal to or below 1.0×10² Ω·cm.

The configuration of the second buffer layer 92 is not limited only to the above-described structure in which the second buffer layer 92 is provided independently of the cathode or the electron transport layer. In other words, the second buffer layer 92 may also have the finction as the cathode or the electron transport layer such as an electron transport-second buffer layer or a cathode-second buffer layer. In terms of the electron transport-second buffer layer, it is possible to use the high-mobility material as describe above. In any case, the second buffer layer 92 can be configured not to have an optical or electric impact except the finction to eliminate the influence of optical interference with the light emission units, unless the second buffer layer is provided with the function of any other layers as described above.

FIG. 29 shows emission spectra of a blue OLED device (A) including a single light emission unit, a blue OLED device (B) including three light emission units, and a blue OLED device (C) including three light emission units and the second buffer layer. The longitudinal axis indicates the light emitting intensity of each device, while the lateral axis indicates the emission wavelength. The CIE chromaticity coordinates of these devices are (0.15, 0.14), (0.14, 0.23), and (0.15, 0.15), respectively.

The device (A) configured to emit light having the emission spectrum (identical to the PL spectrum) indicated with a solid line in the graph has a lamination structure of a transparent electrode (material: ITO, film thickness: 160 nm)/a hole injection layer (a starburst-type material, 60 nm)/a hole transport layer (α-NPD, 20 nm)/a blue light emitting portion (35 nm)/an electron transport layer (Alq₃, 40 nm)/a cathode (Al, 100 nm). Here, the unit (nm) represents the unit of the film thickness in terms of the layer structure, and the unit of the optical film thickness in terms of Lc and the like.

The device (B) configured to emit light having the emission spectrum indicated with continuous black triangle marks in the graph has the MPE structure formed by simply laminating the above-described blue OLED devices each including the single light emission unit. The device (B) is the blue OLED device having a lamination structure of the transparent electrode (ITO, 160 nm)/the hole injection layer (the starburst-type material, 60 nm)/the hole transport layer (α-NPD, 20 nm)/the blue light emitting portion (35 nm)/the electron transport layer (Alq₃, 40 nm)/a charge generating layer (vanadium pentoxide, 30 nm)/the hole injection layer (the starburst-type material, 60 nm)/the hole transport layer (α-NPD, 20 nm)/the blue light emitting portion (35 nm)/the electron transport layer (Alq₃, 40 nm)/the charge generating layer (vanadium pentoxide, 30 nm)/the hole injection layer (the starburst-type material, 60 nm)/the hole transport layer (α-NPD, 20 nm)/the blue light emitting portion (35 nm)/the electron transport layer (Alq₃, 40 nm)/the cathode (Al, 100 nm).

The device (C) configured to emit light having the emission spectrum indicated with continuous white circle marks in the graph has the MPE structure formed by laminating the above-described blue OLED devices each including the single light emission unit. In addition, the second buffer layer is inserted. The second buffer layer has the thickness of 5000 nm and the refractive index of 1.95 relative to the light having the wavelength of 450 nm. The device (C) is the blue OLED device having a lamination structure of the transparent electrode (ITO, 160 nm)/the hole injection layer (the starburst-type material, 60 nm)/the hole transport layer (α-NPD, 20 nm)/the blue light emitting portion (35 nm)/the electron transport layer (Alq₃, 40 nm)/the charge generating layer (vanadium pentoxide, 30 nm)/the hole injection layer (the starburst-type material, 60 nm)/the hole transport layer (α-NPD, 20 nm)/the blue light emitting portion (35 nm)/the electron transport layer (Alq₃, 40 nm)/the charge generating layer (vanadium pentoxide, 30 nm)/the hole injection layer (the starburst-type material, 60 nm)/the hole transport layer (α-NPD, 20 nm)/the blue light emitting portion (35 nm)/the electron transport layer (Alq₃, 40 nm)/the second buffer layer (zinc oxide, 5000 nm)/the cathode (Al, 100 nm).

As compared to the LED device (A) (the solid line in the graph), the LED device (B) (the black triangle marks in the graph) exhibits the different shape of the emission spectrum and considerably different chromaticity due to the significant influence of interference.

Meanwhile, as compared to the LED device (A), the LED device (C) (the continuous white circle marks in the graph) exhibits a different shape of emission spectrum. However, the chromaticity is almost equivalent thereto. That is to say, it is possible to understand from the spectral distribution that the device (C) fails to completely eliminate the optical interference but succeeds in achieving the blue luminescence comparable to that of the LED device (A) in terms of the CIE chromaticity.

In other words, the LED device (C) seems to be more practical as an independent single-color light emitting device as compared to the LED device (B) which results in the blue-green luminescence.

Adjustment of the luminescent color upon formation of the MPE device by laminating the single light emission units “depends on the optical path lengths from the emission interfaces to the reflecting mirror.” There are roughly two adjusting methods applicable. First, in terms of the OLED device including the plurality of light emission units, the values of “the optical path lengths from the emission interfaces to the reflecting mirror” are set substantially equal to, or more than, the coherent length Lc of the emitted light as described above. In this way, it is possible to eliminate the influence of interference and to align the CIE chromaticity of the luminescent color substantially with the luminescence of the OLED device including the single light emission unit. Second, the above-described values of “the optical path lengths from the emission interfaces to the reflecting mirror” are set substantially equal to, or more than, the 2 Lc. In this way, it is possible to significantly diminish or eliminate the influence of interference thoroughly, and thereby to align not only the CIE chromaticity of the luminescent color but also the shape of the emission spectrum substantially with the luminescence of the OLED device including the single light emission unit.

In this embodiment, each of the organic material layers constituting the device has the refractive index of 1.8 relative to the light having the wavelength of 450 nm. Accordingly, there are no interfaces having the difference in the refractive index greater than 0.6 except the interface between the organic material layer and the cathode or the interface between the second buffer layer and the cathode. The optical path length from the light emitting portion to the reflective mirror-electrode (the reflective electrode) is equal to 5075 nm in terms of the MPE device including the second buffer layer. Meanwhile, the optical path length is equal to 75 nm in terms of the MPE device formed by simply laminating the three light emission units without the second buffer layer. Since the value of Lc is equal to 4218 nm and the value of 2 Lc is equal to 8436 nm according to the calculations using the PL spectrum of the blue light-emitting dopant, the MPE device including the second buffer layer satisfies the condition that the optical path length is in the range substantially equal to or above Lc but below 2 LC. In other words, only the chromaticity is aligned with the luminescence of the luminescent material if this condition is satisfied. Accordingly, only the MPE device including the second buffer layer exhibits the same chromaticity as the PL of the luminescent material.

From these results, in the case of forming the OLED device of the MPE structure by simply laminating the single light emission units and inserting the second buffer layer, it is apparent that the luminescent color similar to that of the device having the single light emission unit can be obtained without changing the film thicknesses of the respective light emission units in the laminated structure.

Meanwhile, a similar effect is expected even when the combination of the second buffer layer and the cathode in this embodiment is replaced by a combination of a thick film transparent cathode and a reflecting mirror such as IZO (5000 nm)/Al in particular. In other words, it is possible to locate the second buffer layer closer to the light emitting layer than the transparent cathode.

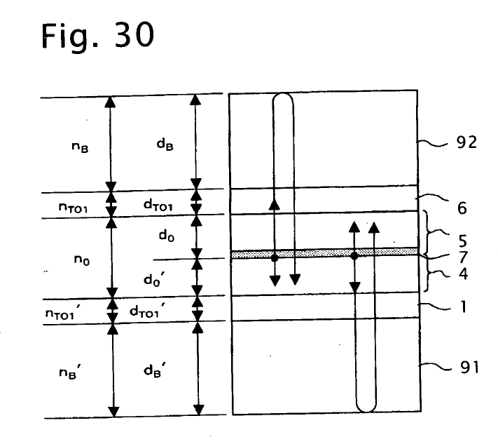

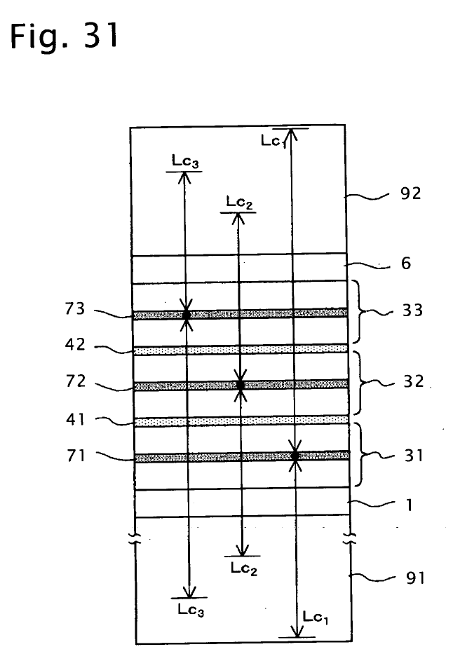

More embodiments according to another aspect of the invention will be described in detail with reference to FIG. 30 and FIG. 31.

FIG. 30 is a cross-sectional view showing a structure of an OLED device according to another embodiment of the invention. A first transparent electrode layer (an anode) 1 is formed on a first transparent buffer region 91, and respective layers and regions of a hole transport layer 4, an organic light emitting layer 5, a second transparent electrode layer (a cathode) 6, and a second transparent buffer region 92 are sequentially formed thereon. In the examples to be described later, a transparent substrate has a function of either the first transparent buffer region 92 or a buffer layer for forming the first transparent buffer region 92.

Moreover, the first transparent buffer region 91 and the second transparent buffer region 92 are formed in a prescribed thickness outside the adjacent first transparent electrode layer 1 and the second transparent electrode layer 6, respectively. To be more precise, the thickness of each of the transparent buffer regions 91 and 92 is set up to achieve an optical path length from an emission interface 7 of the light emitting layer 5 to an outer surface (a light emitting surface to the outside) equal to, or more than, a “coherent length of light emitted from the light emitting layer.”

In the case of an OLED device of a double-sided emission type, it is possible to eliminate an influence of interference by not providing an interfacial plane having a large difference in the refractive index, which may act as a reflection surface causing such interference, in a position at an optical path length from the emission interface shorter than the coherent length Lc. Particularly, by avoiding provision of an interfacial plane having a large difference in the refractive index in a position at an optical path length from the emission interface shorter than Lc on the anode side and the cathode side, it is possible to prevent the light emitted from both surfaces of the device from being affected by the interference. As a result, the light emitted from both the surfaces of the device will have little or no difference in the color tone.

As a consequence, in order to eliminate the influence of interference with the light emitted from the anode side of the OLED device of the double-sided emission type to the outside as shown in FIG. 30, the film thicknesses of the respective layers located in a range between the emission interface 7 to the outer surface (the light emitting surface to the outside) of the second transparent buffer region 92 should be set up to satisfy the following relational expression (3):
Lc≦d₀·n₀+d_{TO1}·n_{TO1}+d_{B}·n_{B} (3)
in which d₀ is a film thickness of the organic light emitting layer 5, n₀ is a refractive index of the organic light emitting layer 5, d_{TO1} is a film thickness of the second transparent electrode layer 6, n_{TO1} is a refractive index of the second transparent electrode layer 6, d_{B} is a distance (or thickness) of the second transparent buffer region 92, and n_{B} is a refractive index of a material existing in the second transparent buffer region 92.

Moreover, in order to eliminate the influence of interference with the light emitted from the cathode side to the outside, the film thicknesses of the respective layers located in a range between the emission interface 7 to the outer surface of the first transparent buffer region 91 should be set up to satisfy the following relational expression (4):
Lc≦d₀′·n₀+d_{TOL}′·n_{TO1}′+d_{B}′·n_{B}′ (4)
in which d₀′ is a film thickness of the hole transport layer 4, n₀′ is a refractive index of the hole transport layer 4, d_{TO1}′ is a film thickness of the first transparent electrode layer 1, n_{TO1}′ is a refractive index of the first transparent electrode layer 1, d_{B}′ is a distance (or thickness) of the first transparent buffer region 91, and n_{B}′ is a refractive index of a material existing in the first transparent buffer region 91.

While an emission region presumably has a certain width inside the light emitting layer, a given position assumed to have high emission intensity will be defined as the emission interface 7. For example, in the simple structure including the hole transport layer 4 and the organic light emitting layer 5 as shown in FIG. 30, the emission intensity presumably reaches the maximum in a region adjacent to the hole transport layer 4 in the organic light emitting layer 5. Accordingly, it is possible to regard the interface between the hole transport layer 4 and the organic light emitting layer 5 as the emission interface 7. Here, the optical path length from the emission interface 7 to the first transparent buffer region 91 and the optical path length from the emission interface 7 to the second transparent buffer region 92 do not have a particular upper limit. However, depending on the application, it may be preferable to set the optical path lengths substantially equal to or below 1000 μm in order not to lose a thin profile advantage of the OLED device. On the contrary, a lower limit of the optical path length can be set to be substantially equal to or above the coherent length Lc, or substantially equal to about two times the Lc value in order to substantially or completely eliminate the influence of interference.

When the single light emitting layer is made of two or more kinds of luminescent materials, the longest of the coherent lengths calculated by use of PL spectra of the respective materials will be applied.

FIG. 31 is a cross-sectional view showing an OLED device according to still another embodiment of the invention. In this embodiment, the MPE structure including a plurality of light emitting positions located separately from one another is used. A similar effect is achieved by the OLED device of this structure as well. In this case, the coherent lengths Lc are calculated in terms of respective luminescent materials of three light emission units by use of applicable PL spectra.

Incidentally, the previously described light emission unit can be used here, and thus the detailed description thereof is omitted.

As for the concrete structure of the OLED device shown in FIG. 31, a first transparent electrode layer (an anode) 1 is formed on a first transparent buffer region 91. Then, a first light emission unit 31 including a first emission interface 71, a first charge generating layer 41, a second light emission unit 32 including a second emission interface 72, a second charge generating layer 42, a third light emission unit 33 including a third emission interface 73, a second transparent electrode layer (a cathode) 6, and a second transparent buffer region 92 are sequentially formed thereon.

To avoid the interference of the light emitted from the respective emission interfaces 71, 72, 73 of these three light emission units 31, 32, 33 in the OLED device structured as described above, the positions of the respective outer surfaces of the first transparent buffer region 91 and the second transparent buffer region 92 are set up as follows. The respective coherent lengths are derived from the PL spectra of the light emitted from the emission interfaces 71, 72, 73 of the respective light emission units 31, 32, 33 by use of the aforementioned relational expression (1). Next, the farthest position on the anode side from the first transparent electrode layer 1 and the farthest position on the cathode side from the second transparent electrode layer 6 are selected from the positions of the coherent lengths away from the respective emission interfaces 71, 72, 73. As a result, positions Lc₁ are located in the farthest positions from the respective transparent electrode layers 1 and 6 on the anode side and on the cathode side as shown in FIG. 31. Accordingly, the respective outer surfaces of the first transparent buffer region 91 and the second transparent buffer region 92 are set up in these positions Lc₁ or in positions still farther from the respective transparent electrode layers 1 and 6 than these positions Lc₁. In this way, it is possible to diminish or eliminate the influence of interference with the light emitted from the respective light emission units 31, 32, 33.

In the configurations shown in FIG. 30 and FIG. 31, each of the first transparent buffer region 91 and the second transparent buffer region 92 may be a layer formed by use of a solid material or a layer formed by filling a gas or a liquid material therein. Layers for forming these buffer regions 91 and 92 will be referred to as buffer layers. The buffer region 91, 92 may be formed of a plurality of buffer layers. When the buffer region 91, 92 includes a plurality of buffer layers, it is ideal to equalize the refractive indices of the respective layers. This is because a difference in the refractive index between two adjacent layers is minimized to avoid the interference of light. Alternatively, it is by all means possible to form the first transparent buffer region 91 as a layer made of a solid material and to form the second buffer region 92 as a layer filled with a liquid material, and vice versa. As will be described later in some examples, it is possible to provide a transparent substrate with the function of the first transparent buffer region 91. It is also possible to form the first transparent buffer region 91 by combining a transparent substrate and a buffer layer to be formed on at least one of main surfaces of the transparent substrate.

As for a liquid transparent material serving as the material for these regions, the various aforementioned materials are applicable.

In the embodiment shown in FIG. 30, interfacial planes located between the emission interface and the outer surface of each transparent buffer region include an interfacial plane between the organic material layers, an interfacial plane between the organic material layer and the transparent electrode layer, and an interfacial plane between the transparent electrode layer and the transparent buffer region. These interfacial planes exist as reflective surfaces in the positions where the optical path lengths from the emission interface may become less than the coherent length Lc. Therefore, these interfacial planes may cause large interference along with an increase in the reflectivity.

Among these interfacial planes, the interfacial plane between the second transparent electrode layer 6 and the second transparent buffer region 92 is likely to form the reflective surface having relatively large reflectivity. For example, when the second transparent buffer region 92 forming the interfacial plane with the second transparent electrode layer 6 is formed into a vacuum or filled with a gas (having the refractive index of approximately 1.0), the difference in the refractive index between the buffer region 92 and the material such as ITO, IZO, ZnO or SnO₂ used as the second transparent electrode layer 6 (having the refractive index of approximately 1.95) is approximately equal to 0.95. This reflective surface having the difference in the refractive index of 0.95 would merely cause a slight influence of interference on the light emitted from the first transparent electrode layer side (anode side) when the optical path length from the emission interface 7 to the interfacial plane between the second transparent electrode layer 6 and the second transparent buffer region 92 is set approximately equal to 300 nm.

On the contrary, the influence of interference on the light emitted from the first transparent electrode side (anode side) will be remarkably large in the OLED device according to the different embodiment of the invention as shown in FIG. 31, which includes the plurality of light emitting positions located separately from one another and thereby requires a very long optical path length from each emission interface to the interfacial plane between the second transparent electrode layer 6 and the second transparent buffer region (gas) 92.

Therefore, in order to suppress occurrence of the interference, it can be important to select the materials for forming the second transparent electrode layer 6 and the second transparent buffer region 92 appropriately in response to the optical path length from each emission interface to the interfacial plane between the second transparent electrode layer 6 and the second transparent buffer region 92, and thereby to adjust the difference in the refractive index therebetween.

In the case of the double-sided emission type OLED device having the optical path length from the emission interface 7 to the interfacial plane between the second transparent electrode layer 6 and the second transparent buffer region 92 approximately equal to 300 nm as shown in FIG. 30, it is possible to set the difference in the refractive index between the second transparent electrode layer 6 and the second transparent buffer region 92 equal to, or less than, 0.6 in order to virtually suppress occurrence of the interference.

Meanwhile, in the case of the double-sided emission type OLED device including the plurality of light emitting positions located separately from one another as shown in FIG. 31, the optical path length from the emission interface to the interfacial plane between the second transparent electrode layer 6 and the second transparent buffer region 92 is increased along with an increase in the number of the light emission units each including at least one light emitting layer. Therefore, it may be helpful to further reduce the difference in the refractive index between the second transparent electrode layer 6 and the second transparent buffer region 92 in this case.

The difference in the refractive index between the second transparent electrode layer 6 and the second transparent buffer region 92, at least in this embodiment, can be zero (0). In this case, it is possible to suppress occurrence of the interference regardless of the optical path length from the emission interface to the interfacial plane between the second transparent electrode layer 6 and the second transparent buffer region 92.

The interference phenomena concerning the light emitted from the emission interface toward the second transparent buffer region 92 in the OLED device have been reviewed from a variety of different angles. It is to be noted, however, that the light emitted from the emission interface toward the transparent substrate (first transparent buffer region 91) similarly concerns the interference phenomena.

In the structure of the OLED device shown in FIG. 30, interfacial planes located between the emission interface and the transparent substrate include an interfacial plane between the organic material layers, an interfacial plane between the organic material layer and the first transparent electrode layer, and an interfacial plane between the first transparent electrode layer and the first transparent buffer region. These interfacial planes exist as reflective surfaces in the positions where the optical path length from the emission interface may become less than the coherent length Lc. Accordingly, there is a possibility of occurrence of interference between light emitted from the emission interface toward the transparent substrate and reflected by any of these interfacial planes and light emitted from the emission interface toward the second transparent electrode layer. Therefore, it may be helpful to suppress occurrence of the interference by reducing the difference in the refractive index between the materials constituting each of the interfacial planes as small as possible.

In particular, the interfacial plane between the first transparent electrode layer 1 and the first transparent buffer region 91 has the largest difference in the refractive index among these three kinds of interfacial planes. For example, in the case of using soda glass (having the refractive index of approximately 1.55) as the first transparent buffer region (transparent substrate) 91 and using a typical material such as ITO, IZO, ZnO or SnO₂ (having the refractive index of approximately 1.95) as the first transparent electrode layer 1, the difference in the refractive index is approximately equal to 0.4. This reflective surface having the difference in the refractive index of approximately 0.4 would hardly cause any influence of interference when the optical path length from the emission interface to the transparent substrate is set approximately equal to 400 nm in the conventional double-sided emission type device. However, the influence of interference will be remarkably large in the OLED device according to the different embodiment of the invention as shown in FIG. 31, which includes the plurality of light emitting positions located separately from one another and thereby requires a very long optical path length from the emission interface to the transparent substrate.

Therefore, in order to suppress occurrence of the interference, it may be helpful to select the materials for forming the first transparent electrode layer 1 and the transparent substrate appropriately in response to the optical path length from the emission interface to the transparent substrate, and thereby to adjust the difference in the refractive index between both structures.

In another modified embodiment, a buffer layer having a very small difference in the refractive index relative to the first transparent electrode layer 1 is formed between the first transparent electrode layer 1 and the transparent substrate in such an appropriate film thickness that the optical path length from the emission interface to the transparent substrate is set equal to, or more than, the coherent length Lc of the light emitted from the light emitting layer. In other words, the buffer region is made of the transparent substrate and the buffer layer. In still another modified embodiment, it is also possible to use a transparent substrate having a very small difference in the refractive index relative to the first transparent electrode layer 1. In this case, it is possible to form the buffer region 91 only by use of the transparent substrate. Accordingly, it is not necessary to provide a buffer layer in addition to the transparent substrate.

Meanwhile, although there is no particular limitation to the material of the transparent substrate having the very small difference in the refractive index relative to the first transparent electrode layer 1, examples thereof include LaSFN9 (made by Schott Glas AG) (having the refractive index of 1.85), for example.

The difference in the refractive index between the first transparent electrode layer 1 and the first transparent buffer region 91 can be zero (0) in this embodiment. In this case, it is possible to suppress occurrence of the interference regardless of the optical path length from the emission interface to the interfacial plane between the first transparent electrode layer 1 and the first transparent buffer region 91.

Incidentally, the previously described materials can be used here as those for the transparent substrate, the first and second transparent electrode layers 1 and 6, and thus the detailed descriptions thereof are omitted.

In addition to the structures shown in FIG. 30 and FIG. 31, the OLED device may have the following various structures: forming the organic material layer on the transparent substrate by sequentially laminating the hole injection layer, the hole transport layer, the light emitting layer, and the electron transport layer viewed from the first transparent electrode layer; forming the organic material layer by sequentially laminating the hole injection layer, the hole transport layer, and the light emitting layer; forming the organic material layer by sequentially laminating the hole transport layer, the light emitting layer, and the electron transport layer; forming the light emitting layer as a multilayer structure; and the like.

Incidentally, the previously described materials can be used here as those for the hole transport layer, the hole injection layer, the electron injection layer, the light emitting layer, and the electron transport layer, and thus the detailed description thereof is omitted.

Next, Examples 21 to 28 and Comparative Examples 7 to 9 concerning OLED devices that are made in accordance with the principles of the invention will be described. Here, in Examples 21 to 27 and Comparative Examples 7 and 8, the structure shown in FIG. 30 was used as a basic structure. Meanwhile, in Example 28 and Comparative Example 9, the structure shown in FIG. 31 was used as a basic structure. Therefore, Examples 21 to 28 will now be described below and Comparative Examples 7 to 9 will be described later.

### Example 21

An ITO transparent electrode constituting the first transparent electrode layer (the anode) 1 was formed in the film thickness of 100 nm on a glass substrate constituting the first transparent buffer region (the transparent substrate) 91 by the sputtering method. The refractive index of the glass substrate was set to 1.55 relative to light having a wavelength of 450 nm. The refractive index of ITO was set to 1.95 relative to the light having the wavelength of 450 nm. Sheet resistance of ITO was set to 10 ohm/sq. Then, the ITO transparent electrode 1 was etched into a given shape, and was subjected to ultrasonic cleaning by use of acetone, isopropyl alcohol, and the like. Thereafter, the ITO transparent electrode 1 was dried. Moreover, this glass substrate 91 was further subjected to UV-O₃ cleaning, and was set in a vacuum deposition chamber. The pressure inside the chamber was reduced to about 1×10⁻⁵ Torr, and the hole transport layer 4 was formed on the ITO transparent electrode 1 in the film thickness of 100 nm. Subsequently, the blue light-emitting material configured to emit the light having the emission spectrum shown in FIG. 8 (hereinafter referred to as the “blue light-emitting dopant”) was codeposited at a concentration of 1% by weight to form the organic light emitting layer 5 in the thickness of 85 nm. Then, a very small amount of the electron injection layer was deposited thereon. Thereafter, an IZO transparent electrode was formed thereon as the second transparent electrode layer (the cathode) 6 in the film thickness of 50 nm by the sputtering method. The refractive index of the organic light emitting layer 5 was set to 1.80 relative to the light having the wavelength of 450 nm. Meanwhile, the refractive index of the IZO transparent electrode 6 was set to 1.95 relative to the light having the wavelength of 450 nm. Furthermore, a UV curable sealing agent, in which gap agents having a size of 18 μm were dispersed, was coated on the outer periphery of the IZO transparent electrode 6. Thereafter, a sealing glass substrate was disposed opposite to the IZO transparent electrode 6, and was attached and fixed thereto. Then, oil having the refractive index of 1.55 was filled in the space surrounded by the IZO transparent electrode 6, the sealing glass substrate, and the sealing agent.

### Examples 22 to 24

In Examples 22 to 24, the OLED devices were formed to have the structure similar to Example 21 except for the configuration that three types of oil having the refractive indices of 1.33, 1.37, and 1.43 were filled in the spaces surrounded by the IZO transparent electrode 6, the sealing glass substrate, and the sealing agent, respectively.

### Example 25

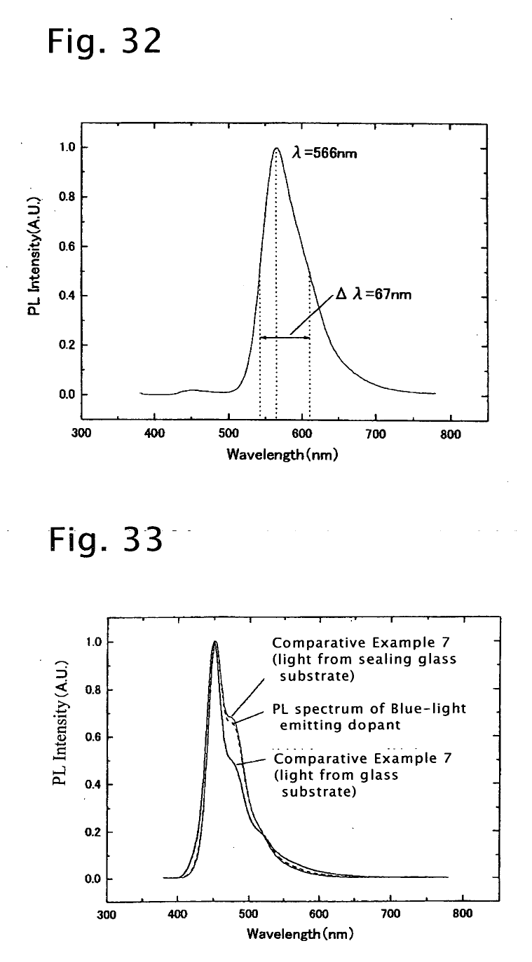

An ITO transparent electrode constituting the first transparent electrode layer (the anode) 1 was formed in the film thickness of 125 nm on a glass substrate constituting the first transparent buffer region (the transparent substrate) 91 by the sputtering method. The refractive index of the glass substrate 91 was set to 1.53 relative to light having a wavelength of 560 nm. The refractive index of ITO was set to 1.90 relative to the light having the wavelength of 560 nm. Sheet resistance of ITO was set to 10 ohm/sq. Then, the ITO transparent electrode 1 was etched into a given shape, and was subjected to ultrasonic cleaning by use of acetone, isopropyl alcohol, and the like. Thereafter, the ITO transparent electrode 1 was dried. This glass substrate 2 was further subjected to UV-O₃ cleaning, and was set in a vacuum deposition chamber. The pressure inside the chamber was reduced to about 1×10⁻⁵ Torr, and the hole transport layer 4 was formed on the ITO transparent electrode 1 in the film thickness of 100 nm. Subsequently, the yellow light-emitting material configured to emit the light having the emission spectrum shown in FIG. 32 (hereinafter referred to as the “yellow light-emitting dopant”) was codeposited at a concentration of 1% by weight to form the organic light emitting layer 5 in the thickness of 80 nm. Then, a very small amount of the electron injection layer was deposited thereon. Thereafter, an IZO transparent electrode was formed thereon as the second transparent electrode layer (the cathode) 6 in the film thickness of 50 nm by the sputtering method. The refractive index of the organic light emitting layer 5 was set to 1.75 relative to the light having the wavelength of 560 nm. Meanwhile, the refractive index of the IZO transparent electrode 6 was set to 1.90 relative to the light having the wavelength of 560 nm. Furthermore, the UV curable sealing agent, in which the gap agents having the size of 18 μm were dispersed, was coated on the outer periphery of IZO transparent electrode 6. Thereafter, a sealing glass substrate was disposed opposite to the IZO transparent electrode 6, and was attached and fixed thereto. Then, oil having the refractive index of 1.55 was filled in a space surrounded by the IZO transparent electrode 6, the sealing glass substrate, and the sealing agent.

### Examples 26 and 27

In Examples 26 and 27, the OLED devices were formed to have the structure similar to Example 25 except for the configuration that two types of oil having the refractive indices of 1.33 and 1.43 were filled in the spaces surrounded by the IZO transparent electrode 6, the sealing glass substrate, and the sealing agent, respectively.

### Example 28

In Example 28, the structure of the OLED device according to the embodiment of the invention shown in FIG. 31 was used as a basic structure. Here, two light emitting positions were provided in this example. To be more precise, an ITO transparent electrode constituting the first transparent electrode layer (the anode) was formed on a glass substrate constituting the transparent substrate by the sputtering method. Sheet resistance of ITO was set to 10 ohm/sq. Then, the ITO transparent electrode 1 was etched into a given shape, and was subjected to ultrasonic cleaning by use of acetone, isopropyl alcohol, and the like. Thereafter, the ITO transparent electrode 1 was dried. The glass substrate was further subjected to UV-O₃ cleaning, and was set in a vacuum deposition chamber. The pressure inside the chamber was reduced to about 1×10⁻⁵ Torr, and the hole transport layer was formed on the ITO transparent electrode 1. Subsequently, the blue light-emitting dopant configured to emit the light having the emission spectrum shown in FIG. 8 at the concentration of 1% by weight was codeposited to form the organic light emitting layer. This lamination structure of the hole transport layer and the organic light emitting layer was defined as a light emission unit 31. After forming the charge generating layer 41 on this light emission unit 31, another light emission unit 32 including the organic light emitting layer with addition of the yellow light-emitting dopant configured to emit the light having the emission spectrum shown in FIG. 32 was formed. Further, a very small amount of the electron injection layer was deposited thereon, and an IZO transparent electrode 6 was formed thereon in the film thickness of 50 nm as the cathode. The refractive index of the organic light emitting layer was set to 1.80 relative to the light having the wavelength of 450 nm. Meanwhile, the refractive index of the IZO transparent electrode 6 was set to 1.95 relative to the light having the wavelength of 450 nm. Furthermore, the UV curable sealing agent, in which the gap agents having the size of 18 μm were dispersed, was coated on the outer periphery of IZO transparent electrode 6. Thereafter, a sealing glass substrate was disposed opposite to the IZO transparent electrode 6, and was attached and fixed thereto. Then, oil having the refractive index of 1.60 was filled in a space surrounded by the IZO transparent electrode 6, the sealing glass substrate, and the sealing agent. In this way, the OLED device including the two separate light emitting positions was finished.

Next, Comparative Examples 7 to 9 will be described.

### Comparative Example 7

The OLED device of Comparative Example 7 had the structure similar to Examples 21 to 24 except for the configuration that N₂ gas was filled in the space surrounded by the IZO transparent electrode 6, the sealing glass substrate, and the sealing agent instead.

### Comparative Example 8

The OLED device of Comparative Example 8 had the structure similar to Examples 25 to 27 except for the configuration that N₂ gas was filled in the space surrounded by the IZO transparent electrode 6, the sealing glass substrate, and the sealing agent instead.

### Comparative Example 9

The OLED device of Comparative Example 9 had the structure similar to Example 28 except for the configuration that N₂ gas was filled in the space surrounded by the IZO transparent electrode 6, the sealing glass substrate, and the sealing agent instead.

### Optical Characteristics of Examples 21-28 and Comparative Examples 7-9

First, optical characteristics of Examples 21 to 24 and Comparative Example 7 will be described. FIG. 33 is a graph showing emission spectra obtained by measuring the light emitted from the glass substrate side and the sealing glass substrate side of the OLED device of the double-sided emission type of Comparative Example 7, and the emission spectrum unique to the blue light-emitting dopant added to the organic light emitting layer, all of which are plotted in the same graph.

In this graph, the distribution of the emission spectrum of the light emitted from the glass substrate side is different from the distribution of the emission spectrum of the light emitted from the sealing glass substrate side. This means that the color tone of the light emitted from the glass substrate side is slightly different from the color tone of the light emitted from the sealing glass substrate side.

Meanwhile, the distribution of the emission spectrum of the light emitted from the sealing glass substrate side is substantially similar to the distribution of the PL (photoluminescent) spectrum of the blue light-emitting dopant. On the contrary, the distribution of the emission spectrum of the light emitted from the glass substrate side is different from the distribution of the PL spectrum of the blue light-emitting dopant.

This phenomenon is presumably due to the following reason. Specifically, there is the difference in the refractive index on an interfacial plane between the ITO transparent electrode and the glass substrate, and the interfacial plane is located in a position where an optical path length from the emission interface is shorter than the coherent length Lc of 4.2 μm derived from the PL spectrum of the blue light-emitting dopant shown in FIG. 8. However, since the interfacial plane acts as a reflection surface having the small difference in the refractive index of 0.4, the light emitted from the sealing glass substrate side is not significantly affected by the interference.

On the contrary, there is the difference in the refractive index on an interfacial plane between the IZO transparent electrode and N₂ gas, and the interfacial plane is located in a position where an optical path length from the emission interface is shorter than the coherent length Lc of 4.2 μm. Since the interfacial plane acts as a reflection surface having the large difference in the refractive index of 0.95, the light emitted from the glass substrate side is significantly affected by the interference.

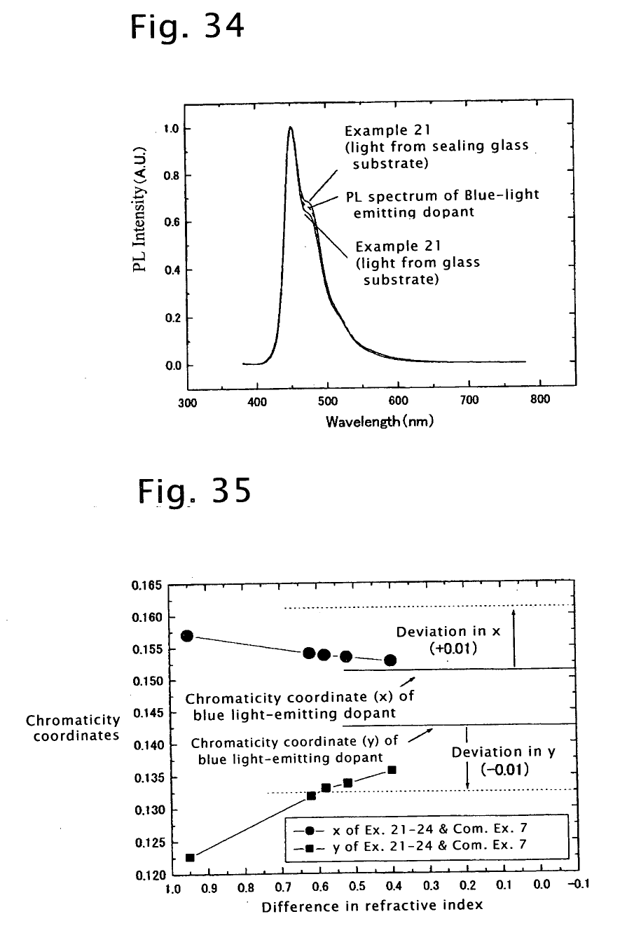

FIG. 34 is a graph showing emission spectra obtained by measuring the light emitted from the glass substrate side and the sealing glass substrate side of the OLED device of the double-sided emission type of Example 21, and the emission spectrum unique to the blue light-emitting dopant added to the organic light emitting layer, all of which are plotted in the same graph.

In this graph, the distribution of the emission spectrum of the light emitted from the glass substrate side is substantially similar to the distribution of the emission spectrum of the light emitted from the sealing glass substrate side, as well as to the distribution of the PL spectrum of the blue light-emitting dopant. This phenomenon is presumably due to the following reason. Specifically, there is the difference in the refractive index on an interfacial plane between the ITO transparent electrode and the glass substrate, and the interfacial plane is located in a position where an optical path length from the emission interface is shorter than the coherent length Lc of 4.2 μm. In addition, there is also the difference in the refractive index on an interfacial plane between the IZO transparent electrode and the oil having the refractive index of 1.55, and the interfacial plane is also located in a position where an optical path length from the emission interface is shorter than the coherent length Lc of 4.2 μm. However, since each of the interfacial planes acts as a reflection surface having the small difference in the refractive index of 0.4, the light emitted from the glass substrate side or the sealing glass substrate side is not significantly affected by the interference.

This means that the color tone of the light emitted from the glass substrate side is substantially the same as the color tone of the light emitted from the sealing glass substrate side, and that the light faithfully reflecting the spectral distribution of the blue light-emitting dopant added to the organic light emitting layer is emitted from both the sides.

Moreover, even when there is the difference in the refractive index in a position where an optical path length from the emission interface is below the coherent length Lc of 4.2 μm, it is apparent that the influence of interference with the light emitted to the outside can be suppressed by minimizing the difference in the refractive index.

FIG. 35 shows relationships between chromaticity coordinates (x, y) of the light emitted from the glass substrate side and the difference in the refractive index caused by the IZO transparent electrode and the material constituting the interfacial plane with the IZO transparent electrode in terms of Examples 21 to 24 and Comparative Example 7. From this drawing, it is apparent that the influence of interference with the light emitted from the glass substrate side becomes smaller along with a decrease in the difference in the refractive index. As a consequence, the chromaticity coordinates (x, y) of the light emitted from the glass substrate side gradually approach the chromaticity coordinates (x, y) derived from the PL spectrum unique to the blue light-emitting dopant.

Moreover, when the difference in the refractive index is substantially equal to or below 0.6, deviation from the chromaticity coordinates (x, y) of the blue light-emitting dopant becomes substantially equal to or below 0.01 in terms of the x value and the y value. In this way, it was apparent that the deviation of the chromaticity could be suppressed to an indiscernible level in terms of the color discrimination power of a human being.

From these results, it was apparent that the difference in the refractive index might cause the interference even at the value around 0.95, provided that the difference in the refractive index exists in the position where the optical path length from the emission interface of the organic light emitting layer is shorter than the coherent length Lc. Moreover, it was apparent that the influence of interference could be suppressed by minimizing the difference in the refractive index.

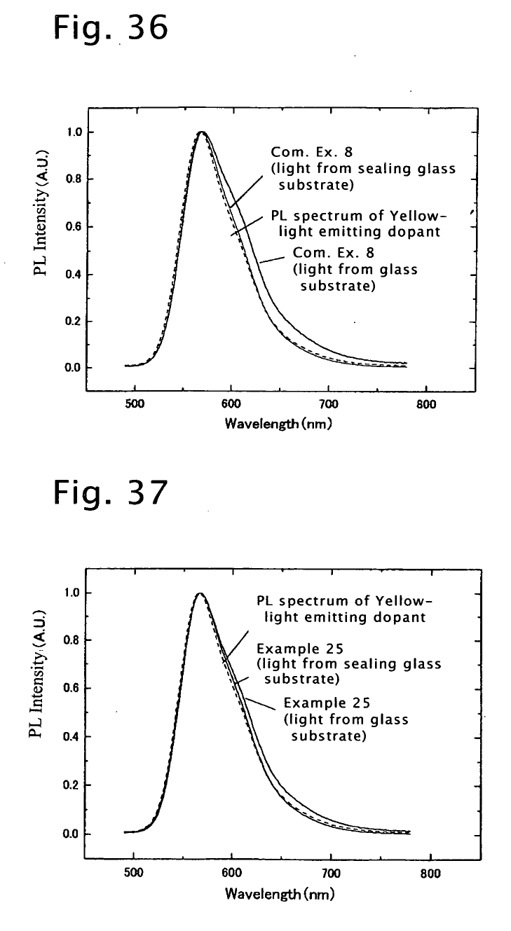

Next, optical characteristics of Examples 25 to 27 and Comparative Example 8 will be described. FIG. 36 is a graph showing emission spectra obtained by measuring the light emitted from the glass substrate side and the sealing glass substrate side of the OLED device of the double-sided emission type of Comparative Example 8, and the emission spectrum unique to the yellow light-emitting dopant added to the organic light emitting layer, all of which are plotted in the same graph.

In this graph, the distribution of the emission spectrum of the light emitted from the glass substrate side is different from the distribution of the emission spectrum of the light emitted from the sealing glass substrate side. This means that the color tone of the light emitted from the glass substrate side is slightly different from the color tone of the light emitted from the sealing glass substrate side.

Meanwhile, the distribution of the emission spectrum of the light emitted from the sealing glass substrate side is substantially similar to the distribution of the PL (photoluminescent) spectrum of the yellow light-emitting dopant. On the contrary, the distribution of the emission spectrum of the light emitted from the glass substrate side is different from the distribution of the PL spectrum of the yellow light-emitting dopant.

This phenomenon is presumably due to the following reason. Specifically, there is the difference in the refractive index on an interfacial plane between the ITO transparent electrode and the glass substrate, and the interfacial plane is located in a position where an optical path length from the emission interface is shorter than the coherent length Lc of 4.8 μm derived from the PL spectrum of the blue light-emitting dopant shown in FIG. 32. However, since the interfacial plane acts as a reflection surface having the small difference in the refractive index of 0.37, the light emitted from the sealing glass substrate side is not significantly affected by the interference.

On the contrary, there is the difference in the refractive index on an interfacial plane between the IZO transparent electrode and N₂ gas, and the interfacial plane is located in a position where an optical path length from the emission interface is shorter than the coherent length Lc of 4.8 μm. Since the interfacial plane acts as a reflection surface having the large difference in the refractive index of 0.90, the light emitted from the glass substrate side is significantly affected by the interference.

FIG. 37 is a graph showing emission spectra obtained by measuring the light emitted from the glass substrate side and the sealing glass substrate side of the OLED device of the double-sided emission type of Example 25, and the emission spectrum unique to the yellow light-emitting dopant added to the organic light emitting layer, all of which are plotted in the same graph.

In this graph, the distribution of the emission spectrum of the light emitted from the glass substrate side is substantially similar to the distribution of the emission spectrum of the light emitted from the sealing glass substrate side, as well as to the distribution of the PL spectrum of the yellow light-emitting dopant. This phenomenon is presumably due to the following reason. Specifically, there is the difference in the refractive index on an interfacial plane between the ITO transparent electrode and the glass substrate, and the interfacial plane is located in a position where an optical path length from the emission interface is shorter than the coherent length Lc of 4.8 μm. In addition, there is also the difference in the refractive index on an interfacial plane between the IZO transparent electrode and the oil having the refractive index of 1.55, and the interfacial plane is also located in a position where an optical path length from the emission interface is shorter than the coherent length Lc of 4.8 μm. However, since each of the interfacial planes acts as a reflection surface having the small difference in the refractive index of 0.37 or 0.35, the light emitted from the glass substrate side or the sealing glass substrate side is not significantly affected by the interference.

This means that the color tone of the light emitted from the glass substrate side is substantially the same as the color tone of the light emitted from the sealing glass substrate side, and that the light faithfully reflecting the spectral distribution of the yellow light-emitting dopant added to the organic light emitting layer is emitted from both sides.

Moreover, even when there is the difference in the refractive index in a position where an optical path length from the emission interface is below the coherent length Lc of 4.8 μm, it is apparent that the influence of interference with the light emitted to the outside can be suppressed by minimizing the difference in the refractive index.

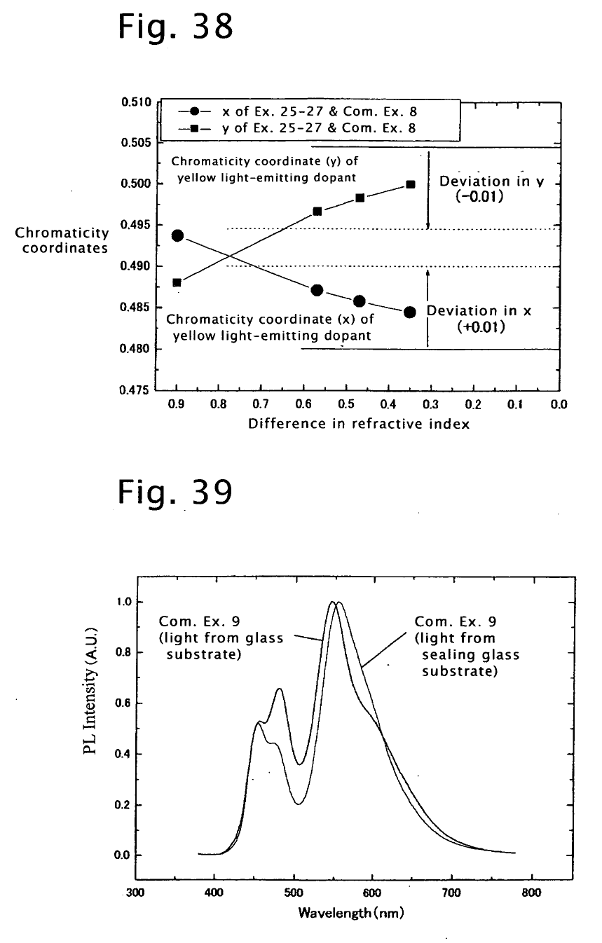

FIG. 38 shows relationships between chromaticity coordinates (x, y) of the light emitted from the glass substrate side and the difference in the refractive index caused by the IZO transparent electrode and the material constituting the interfacial plane with the IZO transparent electrode in terms of Examples 25 to 27 and Comparative Example 8. From this drawing, it is apparent that the influence of interference with the light emitted from the glass substrate side becomes smaller along with a decrease in the difference in the refractive index. As a consequence, the chromaticity coordinates (x, y) of the light emitted from the glass substrate side gradually approach the chromaticity coordinates (x, y) derived from the PL spectrum unique to the yellow light-emitting dopant.

Moreover, when the difference in the refractive index is substantially equal to or below 0.6, deviation from the chromaticity coordinates (x, y) of the yellow light-emitting dopant becomes substantially equal to or below 0.01 in terms of the x value and the y value.

On the assumption that there are a plurality of OLED devices having the differences in the refractive index in positions having substantially the same optical path length from the emission interface, it is possible to reduce the deviation of the chromaticity as the wavelength of the light emitted from the emission interface is longer even in the case of a relatively large difference in the refractive index. Incidentally, the human eye has higher sensitivity to detect a difference in the chromaticity in a blue zone, and has lower sensitivity in other color zones such as a green zone, a yellow zone, or a red zone as compared to the blue zone. In other words, the human eye can detect a slight difference in the chromaticity of the light in the blue zone but can detect only a larger difference in the chromaticity of the light in the green, yellow, and red zones.

Accordingly, when the difference in the refractive index exists in the position where the optical path length from the emission interface is shorter than the coherent length Lc, it is desirable to set the difference in the refractive index substantially equal to or below 0.6 and thereby to suppress the deviation of the chromaticity coordinates (x, y) substantially equal to or below 0.01. In this way, it is possible to obtain luminance in a desired color tone in any color tone perspectives, which can be recognized as equivalent to the original luminescent color of the luminescent material.

Next, optical characteristics of Example 28 and Comparative Example 9 will be described. FIG. 39 is a graph showing emission spectra obtained by measuring the light emitted from the glass substrate side and the sealing glass substrate side of the OLED device of the double-sided emission type of Comparative Example 9, all of which are plotted in the same graph.

In this graph, the distribution of the emission spectrum of the light emitted from the glass substrate side is significantly different from the distribution of the emission spectrum of the light emitted from the sealing glass substrate side. This means that the color tone of the light emitted from the glass substrate side is significantly different from the color tone of the light emitted from the sealing glass substrate side.

Here, in terms of the light emitted from the sealing glass substrate side, the spectral distribution on the wavelength range shorter than 500 nm is close to the distribution of the PL spectrum of the blue light-emitting dopant shown in FIG. 8. Meanwhile, the spectral distribution on the wavelength range longer than 510 nm is close to the distribution of the PL spectrum of the yellow light-emitting dopant shown in FIG. 32. As similar to Comparative Examples 7 and 8, these phenomena are presumably due to the relatively small difference in the refractive index between the glass substrate and the ITO transparent electrode.

Meanwhile, the coherent length Lc derived from the PL spectrum of the blue light-emitting dopant shown in FIG. 8 is approximately equal to 4.2 μm, and the coherent length Lc derived from the PL spectrum of the yellow light-emitting dopant shown in FIG. 32 is approximately equal to 4.8 μm. Therefore, in terms of the light emitted from the glass substrate side, it may be preferable to avoid at least an interfacial plane having a large difference in the refractive index in a position where an optical path length from the emission interface configured to emit yellow light is shorter than 4.8 μm. Nevertheless, the reflection surface having the difference in the refractive index of 0.95 exists between the IZO transparent electrode and N₂ gas constituting the interfacial plane with the IZO transparent electrode. Accordingly, the light emitted from the glass substrate side is presumably affected by the interference.

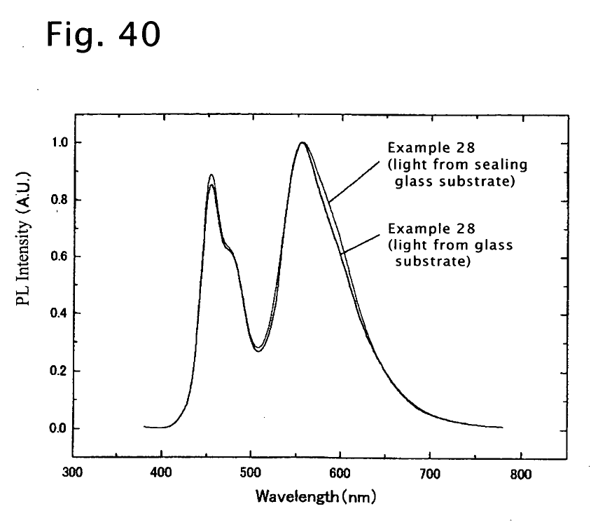

FIG. 40 is a graph showing emission spectra obtained by measuring the light emitted from the glass substrate side and the sealing glass substrate side of the OLED device of the double-sided emission type of Example 28, both of which are plotted in the same graph. In Example 28, oil having the refractive index of 1.60 was used as the material constituting an interfacial plane with the IZO transparent electrode, and the difference in the refractive index between them was set to 0.35.

In terms of the light emitted from the glass substrate side, the spectral distribution on the wavelength range shorter than 500 nm is close to the distribution of the PL spectrum of the blue light-emitting dopant shown in FIG. 8 as similar to the light emitted from the sealing glass substrate side. In addition, the spectral distribution on the wavelength range longer than 510 nm is close to the distribution of the PL spectrum of the yellow light-emitting dopant shown in FIG. 32. As a result, the color tone of the light emitted from the sealing glass substrate side substantially coincides with the color tone of the light emitted from the glass substrate side. Meanwhile, in Examples 21 to 28, the second transparent buffer regions are made of the oil layers having various refractive indices. Here, it is also possible to form the second transparent buffer region by use of the oil layer and the sealing glass substrate. However, the coherent length of the emitted light from the emission interface exists in the region of the sealing glass substrate. Accordingly, the difference in the refractive index between the oil layer and the sealing glass substrate should be set substantially equal to or below 0.6.

In other words, the influence of interference with the light emitted to the outside is effectively suppressed by minimizing the difference in the refractive index located at the optical path length from the emission interface being shorter than the coherent length Lc.

As described above, the OLED device can include the organic material layer interposed between the two opposed transparent electrodes, and the organic material layer can include the plurality of light emission units each including at least one light emitting layer. In addition, the OLED device can have the structure of the double-sided emission type, in which the respective light emission units are partitioned by at least one layer of the charge generating layer. It is apparent that this OLED device can achieve the effects similar to an OLED device having one light emitting layer.

Here, suppose the case where the deviations of the chromaticity coordinates (x, y) of the light emitted from the sealing glass substrate side and the glass substrate side are reduced equal to or below 0.01 in terms of the x values and the y values relative to the chromaticity coordinate (x, y) expected from the PL spectrum unique to the luminescent material. In this case, if the x values and/or the y values of the light emitted from the sealing glass substrate side and the glass substrate side have mutually different signs and the sum of the absolute values thereof is equal to, or more than, 0.01 on the basis of the chromaticity coordinates (x, y) expected from the PL spectrum unique to the luminescent material (for example, x and y values are +0.004 and −0.007, respectively), the deviation in the chromaticity of the light emitted from both the sides does not remain within 0.01. In this case, the light exhibit the color tones which are slightly different from each other.

This phenomenon can be appropriately dealt with by reducing the difference in the refractive index, inverting a magnitude correlation of the refractive indices between the materials on the interfacial plane causing the difference in the refractive index, adjusting the film thicknesses or the optical film thicknesses of the respective layers, and so forth.

Now, some of the advantages and operating characteristics of various embodiments and examples of the invention will be described. First, the OLED device can be formed by depositing a first transparent electrode layer (an anode) on a first transparent buffer region, and then sequentially forming a hole transport layer, an organic light emitting layer, a second transparent electrode layer (a cathode), and a second transparent buffer region. In this way, the OLED device is configured to emit the light from the first transparent buffer region side and the second transparent buffer region side. Moreover, the difference in the refractive index on the interfacial plane existing in the position where the optical path length from the emission interface is shorter than the coherent length Lc derived from the PL spectrum of the light emitted from the emission interface of the organic light emitting layer is set approximately equal to, or less than, 0.6. Now, the following advantages are achieved by the above-described OLED device. Here, the coherent length Lc is calculated by Lc=λ²/Δλ (in which λ is a central wavelength of a PL spectrum, and Δλ is a spectral half bandwidth)

(1) It is possible to eliminate the influence of interference with the light emitted from the first transparent buffer region side and the second transparent buffer region side.

(2) By using the advantage (1), it is possible to reduce the deviation of the chromaticity coordinates (x, y) of the light emitted from the first transparent buffer region side and the second transparent buffer region side equal to or below 0.01 in terms of the x values and the y values relative to the chromaticity coordinates (x, y) expected from the PL spectrum unique to the luminescent material.

(3) As a result, the color tone of the light emitted from the first transparent buffer region side substantially coincides with the color tone of the light emitted from the second transparent buffer region side.

(4) Moreover, the color tones of the light emitted from the first transparent buffer region side and the second transparent buffer region side substantially coincide with the color tone derived from the PL spectrum unique to the luminescent material.

(5) By setting the difference in the refractive index on the interfacial plane existing in the position where the optical path length from the emission interface is shorter than the coherent length Lc derived from the PL spectrum of the light emitted from the emission interface of the organic light emitting layer approximately equal to or below 0.6, the film thicknesses of the respective layers constituting the device can be set up without considering the influence of interference. Accordingly, it is possible to realize the OLED device having enhanced light extraction efficiency with an attempt to optimize carrier transport, recombination, and light emission.

(6) The spectral distribution (the color tone) of the outgoing light does not change along with a change in the film thickness. In this way, it is possible to improve yields in the manufacturing process and thereby to enhance productivity.

(7) There is also provided OLED devices according to different embodiments of the invention. To form the OLED device, a first transparent electrode layer (an anode) is deposited on a first transparent buffer region. Then, a plurality of light emission units each having a light emitting layer are provided thereon. Here, a charge generating layer is interposed therebetween. Moreover, a second transparent electrode layer (the cathode) is formed thereon, and a second transparent buffer region is further formed on the second transparent electrode layer. This OLED device can also achieve the same and other advantages as those described above.

While there has been described what are at present considered to be preferred and exemplary embodiments of the invention, it will be understood that various modifications may be made thereto, and it is intended that the appended claims cover all such modifications as fall within the true spirit and scope of the invention.

What is claimed is:

1. A light emitting diode device, comprising:
a pair of electrodes; and
a thin film multilayer structure located adjacent the pair of electrodes and including at least one light emitting layer, the light emitting layer including an emission interface; wherein
the device has adjacent layers having an interfacial plane therebetween, the interfacial plane disposed in a position such that an optical path length from the emission interface to the interfacial plane is substantially equal to, or less than, a coherent length of light emitted from the emission interface, and
a difference in refractive index between the adjacent layers is substantially equal to, or less than, 0.6.

2. The light emitting diode device according to claim 1, further comprising:
a reflecting mirror disposed in a position such that an optical path length from the emission interface to the reflecting mirror is substantially equal to, or more than, the coherent length of light emitted from the emission interface.

3. The light emitting diode device according to claim 2, wherein:
the pair of electrodes are transparent electrodes; and
the reflecting mirror is at least one of in contact with an outer surface of one of the transparent electrodes and disposed in a position spaced from an outer surface of one of the transparent electrodes.

4. The light emitting diode device according to claim 3, further comprising:
a buffer layer disposed at least one of outside one of the transparent electrodes and between one of the transparent electrodes and the reflecting mirror.

5. The light emitting diode device according to claim 4, wherein
the buffer layer is formed as at least one of a vacuum and a material selected from the group consisting of a transparent material and a gas.

6. The light emitting diode device according to claim 2, wherein
the thin film multilayer structure is composed of a plurality of light emitting units each having at least one light emitting layer, and
a charge generating layer is formed between the light emitting units.

7. The light emitting diode device according to claim 1, wherein
one of the pair of electrodes is a transparent electrode and the other electrode is a reflecting electrode disposed in a position such that an optical path length from the emission interface to the reflecting electrode is substantially equal to, or more than, the coherent length of light emitted from the emission interface.

8. The light emitting diode device according to claim 7, further comprising:
a buffer layer disposed at least one of outside the transparent electrode and between the transparent electrode and the reflecting electrode.

9. The light emitting diode device according to claim 8, wherein
the thin film multilayer structure is composed of a plurality of light emitting units each having at least one light emitting layer, and
a charge generating layer is formed between the light emitting units.

10. The light emitting diode device according to claim 1, further comprising:
at least one buffer layer, wherein
the pair of electrodes are transparent electrodes,
the at least one buffer layer is formed outside the pair of transparent electrodes, and
the coherent length of the light emitted from the emission interface is located within the at least one buffer layer.

11. The light emitting diode device according to claim 10, wherein,
the thin film multilayer structure is composed of a plurality of light emitting units each having at least one light emitting layer, and
a charge generating layer is formed between the light emitting units.

12. The light emitting diode device according to claim 1, wherein the pair of electrodes are opposed to each other, and the thin film multilayer structure is interposed between the pair of electrodes.

13. A light emitting diode device, comprising:
at least one electrode;
a thin film multilayer structure located adjacent the at least one electrode and including at least one light emission interface;
a mirror surface spaced from the emission interface such that an optical path length from the light emission interface to the mirror surface is substantially equal to, or more than, a coherent length of light emitted from the emission interface, and a difference in refractive index is substantially equal to, or less than, 0.6, for all adjacent layers between the emission interface and the mirror surface.

14. The light emitting diode device according to claim 13, wherein the mirror surface is formed at an interfacial plane located between adjacent layers of the multilayer structure.

15. The light emitting diode device according to claim 13, wherein
the at least one electrode is a transparent electrode, and
the mirror is at least one of in contact with an outer surface of the at least one transparent electrode and disposed in a position spaced from an outer surface of the at least one transparent electrode.

16. The light emitting diode device according to claim 15, further comprising:
a buffer layer disposed at least one of outside of the at least one transparent electrode and between the at least one transparent electrode and the mirror.

17. The light emitting diode device according to claim 16, wherein
the buffer layer is formed as at least one of a vacuum and a material selected from the group consisting of a transparent material and a gas.

18. The light emitting diode device according to claim 13, wherein
the thin film multilayer structure is composed of a plurality of light emitting units each having at least one light emitting layer, and
a charge generating layer is formed between the light emitting units.

19. The light emitting diode device according to claim 13, wherein
the at least one electrode includes a transparent electrode and a reflecting electrode, the reflecting electrode disposed in a position such that an optical path length from the emission interface to the reflecting electrode is substantially equal to, or more than, the coherent length of light emitted from the emission interface;
a buffer layer is disposed at least one of outside the transparent electrode and between the transparent electrode and the reflecting electrode.

20. The light emitting diode device according to claim 19, wherein
the thin film multilayer structure is composed of a plurality of light emitting units each having at least one light emitting layer; and
a charge generating layer is formed between the light emitting units.
